(19) United States
(12) Patent Application Publication
(10) Pub. No.: US 2024/0407083 A1
(43) Pub. Date: Dec. 5, 2024

(54) SYSTEM AND METHOD FOR TRACE GENERATION AND RECONFIGURATION ON A BREADBOARD OR PRINTED CIRCUIT BOARD

(71) Applicant: Albert Moses Haim, Potomac, MD (US)

(72) Inventor: Albert Moses Haim, Potomac, MD (US)

(21) Appl. No.: 18/800,040

(22) Filed: Aug. 10, 2024

Related U.S. Application Data
(63) Continuation-in-part of application No. 17/832,069, filed on Jun. 3, 2022.
Application No. 17/832,069 is a continuation of application No. 17/500,804, filed on Oct. 13, 2021, now Pat. No. 11,363,713.

(51) Int. Cl. H05K 1/02; G06F 30/34; G06F 30/347; G06F 30/392; H05K 1/11

(52) U.S. Cl. CPC H05K 1/0289; G06F 30/34; G06F 30/347; G06F 30/392; H05K 1/029; H05K 1/115

(57) ABSTRACT

A dynamically reconfigurable circuit, method and computer program product, includes a photoconductive layer responsive to light, wherein the photoconductive layer modifies an electrical conductivity thereof in accordance with a pattern of light projected onto the photoconductive layer; a digital light processing (DLP) module configured to project the pattern of light onto the photoconductive layer, wherein the light is selectively patterned to reconfigure circuit pathways within the photoconductive layer; and a memory coupled to the DLP module, the memory configured to store configuration data and instructions for controlling the light patterns projected by the DLP module.

### CROSS REFERENCE TO RELATED DOCUMENTS

The present invention is a continuation-in-part of U.S. patent application Ser. No. 17/832,069 of Albert Moses HAIM, entitled “SYSTEM AND METHOD FOR TRACE GENERATION AND RECONFIGURATION ON A BREADBOARD OR PRINTED CIRCUIT BOARD,” filed on 03 Jun. 2022, now pending, which is a continuation of U.S. patent application Ser. No. 17/500,804 of Albert Moses HAIM, entitled “SYSTEM AND METHOD FOR TRACE GENERATION AND RECONFIGURATION ON A BREADBOARD OR PRINTED CIRCUIT BOARD,” filed on 13 Oct. 2021, now U.S. Pat. No. 11,363,713, the entire disclosures of all of which are hereby incorporated by reference herein.

### BACKGROUND OF THE DISCLOSURE

### Field Of The Disclosure

The present disclosure generally relates to circuit boards, breadboards, and the like, and more particularly to a method and system for printed circuit boards, breadboards, and the like, having reconfigurable traces, circuit lines, and the like.

### DISCUSSION OF THE BACKGROUND

Whether using a breadboard in electronics hobby, educational scenario or a company lab, building a circuit with a breadboard and translating the connections to a printed circuit board (PCB) can be challenging. Sometimes connections are missed or mismatched when drawing up a circuit based on a breadboard design. This is especially true if you have large numbers of jumper wires. If you are building a breadboard circuit based on a circuit simulator design, or just working from a paper design, or are ready to take the breadboard design to the computer for simulation or PCB manufacture, translation errors often occur. The time spent in circuit design, troubleshooting and manufacture can be lengthy using these current implements. Even when you have reached the PCB stage in your design, there could be flaws in the trace design, or flawed discrete components over time, rendering the PCB a waste, specifically called e-waste, for electronics waste, which contributes to major pollution of the planet.

### SUMMARY OF THE DISCLOSURE

Therefore, there is a need for a method and system that addresses the above and other problems. The above and other problems are addressed by the illustrative embodiments of the present disclosure, which provide a smart breadboard, or smart printed circuit board which can connect to a computer, such that the computer software and user can download trace geometry onto said smart breadboard or smart printed circuit board. In this fashion, no jumper wires are needed, or are greatly reduced. Also, the traces designed on the computer can easily be verified on the smart breadboard or smart printed circuit board, and a regular, more inexpensive printed circuit board can be made with assurance that the connections are valid. Time making and troubleshooting circuits is saved with this methodology.

Accordingly, in illustrative aspects of the present disclosure there is provided a dynamically reconfigurable circuit, method and computer program product, including a photoconductive layer responsive to light, wherein the photoconductive layer modifies an electrical conductivity thereof in accordance with a pattern of light projected onto the photoconductive layer; a digital light processing (DLP) module configured to project the pattern of light onto the photoconductive layer, wherein the light is selectively patterned to reconfigure circuit pathways within the photoconductive layer; and a memory coupled to the DLP module, the memory configured to store configuration data and instructions for controlling the light patterns projected by the DLP module.

The reconfigurable circuit, method and computer program product include a feedback loop operatively connected to the DLP module and configured to generate real-time data from the photoconductive layer, wherein the DLP module is configured to adjust the light patterns in response to the real-time data.

The reconfigurable circuit, method and computer program product include a processor in communication with the DLP module and the feedback loop and configured to execute instructions stored in the memory to manage dynamic reconfiguration of the photoconductive layer.

The digital light processing (DLP) module comprises an on-chip sapphire laser configured to project the light patterns onto the photoconductive layer.

The photoconductive layer comprises an Inverse Faraday Effect (IFE) photo-magnetic nanoparticle layer, configured to alter magnetic and electrical properties thereof in response to light and magnetic fields.

The circuit is implemented as an Application-Specific Integrated Circuit (ASIC).

Still other aspects, features, and advantages of the present disclosure are readily apparent from the following detailed description, by illustrating a number of illustrative embodiments and implementations, including the best mode contemplated for carrying out the present disclosure. The present disclosure is also capable of other and different embodiments, and its several details can be modified in various respects, all without departing from the spirit and scope of the present disclosure. Accordingly, the drawings and descriptions are to be regarded as illustrative in nature, and not as restrictive.

### BRIEF DESCRIPTION OF THE DRAWINGS

The embodiments of the present disclosure are illustrated by way of example, and not by way of limitation, in the figures of the accompanying drawings and in which like reference numerals refer to similar elements and in which:

FIG. 1 is an illustrative overview of a smart breadboard or smart printed circuit board (e.g., solderboard, and the like) and components thereof, enabling trace reconfiguration, visualization of traces, and the like;

FIG. 2 is an illustrative more detailed overview of hardware employed to enable trace reconfiguration, as well as integrated test instruments;

FIG. 3 is an illustrative view of a switching matrix employed to enable trace geometries on a smart breadboard or smart printed circuit board;

FIG. 4 is an illustrative view of a smart breadboard or smart printed circuit board, with components attached and connected via generated reconfigurable traces;

FIG. 5 is an illustrative example of an embodiment of a switching matrix, using PhotoMOS technology, and the like;

FIG. 6 is an illustrative example of an embodiment of a switching matrix, using phototransistors in a TRIAC configuration, and the like;

FIG. 7 is an illustrative example of an embodiment of a switching matrix, using Micro-Electro-Mechanical Systems (MEMS) photo-coupled switches, and the like;

FIG. 8 is an illustrative example of an embodiment of a switching matrix, using optocoupler switches, and the like;

FIG. 9 is an illustrative view of a workbench configuration used to design circuitry employing a smart breadboard or smart printed circuit board;

FIG. 10 is an illustrative example of a circuit implemented on a smart breadboard, to turn on/off the circuit on the breadboard by the smart breadboard, or alternatively turn off the smart breadboard by the circuit on the smart breadboard;

FIG. 11 is an illustrative example of a circuit within a smart breadboard to power it on, or power it off;

FIG. 12 is an illustrative web application that supports a smart breadboard or smart printed circuit board as Internet of Things (IoT) with various features, functionality, and the like;

FIGS. 13A-13B are an illustrative example of software logic that determines how to fix a circuit on a smart breadboard using reconfigurable traces and integrated test and measurement devices, when something is wrong with the circuit on a smart breadboard or smart PCB, and the like;

FIG. 14 is an illustrative representation of a proof-of-concept prototype for a magnetically induced conductivity system, which can be used as a Bipolar Magnetic Field Effect Transistor (MFET) utilizing a steel powder layer and a movable magnet;

FIG. 15 is an illustrative depiction of a magnetically controlled conductive path formation system, utilizing programmed magnetic domains and steel powder to create or disrupt electrical conductivity;

FIG. 16 is an illustrative depiction of a manufacturing process for creating a chip with optically controlled gate arrays using UV light exposure on a photoconductive layer;

FIG. 17 is an illustrative depiction of a reconfigurable circuit system that utilizes an electromagnet array to manipulate a steel powder layer, enabling dynamic circuit configuration;

FIG. 18 is an illustrative representation of a reconfigurable photonic circuit system that can utilize a combination of UV light, a photoconductor layer, and a transparent LCD to dynamically alter circuit configurations with high precision;

FIG. 19 is an illustrative representation of a dynamic light-responsive circuit system, showcasing various components such as photo transistors, photo resistors, photo inductors, photo capacitors, and a photo ground plane;

FIG. 20 is an illustrative system for reconfigurable circuit design housed within a plexiglass enclosure, where a dynamic interplay between light and a photoconductive gel layer facilitates real-time circuit reconfiguration;

FIG. 21 is an illustrative system that showcases a layered assembly designed for reconfigurable circuit applications using light-responsive materials;

FIG. 22 is an illustrative representation of an A.I.-driven/assisted DLP system integrated with a dynamic photonic chip for real-time reconfigurable circuitry;

FIG. 23 illustrates a sophisticated system designed for dynamically reconfigurable circuitry using advanced materials and AI-driven controls;

FIG. 24 is an illustrative setup showcasing a sophisticated photonic circuit system designed for dynamic reconfiguration and real-time monitoring through advanced optical and electronic integration;

FIG. 25 is an illustrative setup that demonstrates a complex and adaptable photonic circuit system designed to leverage advanced materials and dynamic optical control for the reconfiguration of electronic circuits in real-time; and

FIG. 26 is an illustrative setup showcasing an advanced photonic and electronic system designed for dynamic reconfiguration of circuitry using light-based inputs, real-time feedback mechanisms, and integrated wireless communication technologies.

### DETAILED DESCRIPTION OF THE PREFERRED EMBODIMENTS

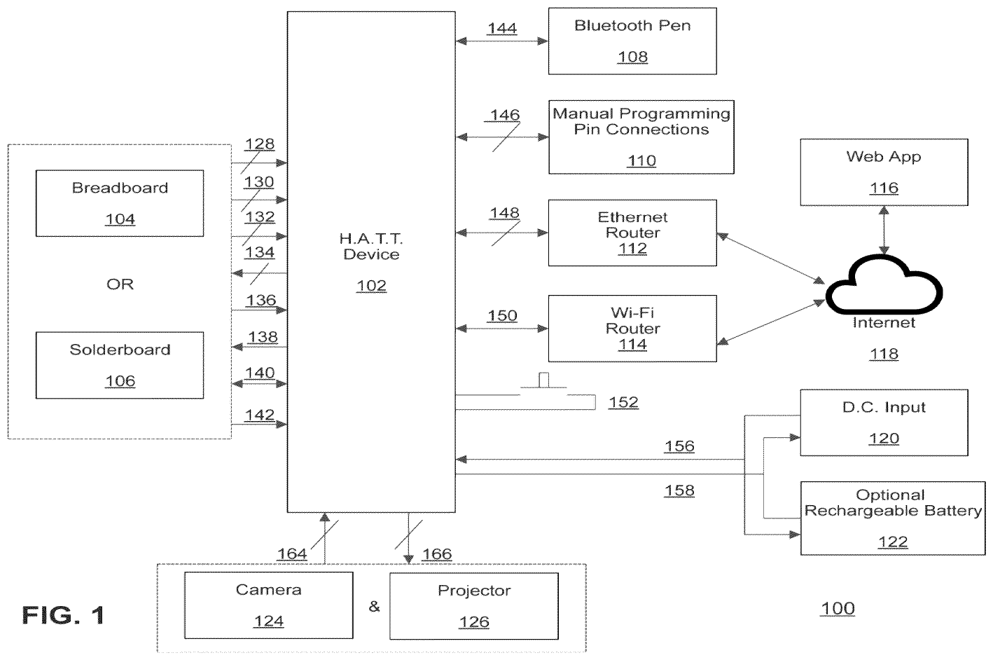

Referring now to the drawings, wherein like reference numerals designate identical or corresponding parts throughout the several views, and more particularly to FIG. 1 thereof, there is illustrated an overview of the smart breadboard or smart printed circuit board (e.g., a solderboard, and the like) and its components, enabling the method and system for trace reconfiguration, and visualization of the traces, according to an illustrative embodiment. In FIG. 1, system 100 shows a H.A.T.T. device 102 connected to a web application 116 across the internet 118 via connection 148 to ethernet router 112, or via wireless connection 150 to Wi-Fi router 114. The web application 116, which can be implemented with Bubble.io or the like, serves to draw circuit traces on a computer, among other things, which can then be downloaded to the H.A.T.T. device 102, which are then translated to circuit traces or trace geometry on the breadboard 104 or solderboard 106, via connections 134. A Bluetooth pen 108, and the like, wirelessly connected via 144 can also serve to draw traces on the breadboard 104 or solderboard 106, which can be seen by a projection of those traces by projector 126 onto the breadboard 104 or solderboard 106. Alternatively, trace geometry can be uploaded onto the H.A.T.T. device 102 via manual programming pin connections 110, connected via 146. To view trace geometry on the breadboard 104 or solderboard 106, a camera 124 connected via 164 and projector 126 connected via 166 are employed to align and project the trace geometry onto the breadboard 104 or solderboard 106. To turn the H.A.T.T. device 102 on or off, there is a switch 152, which, when pressed once, turns the H.A.T.T. device 102 on, and when pressed twice, turns it off. Power to the H.A.T.T. device 102 can be sourced by a D.C. Input 120, or a rechargeable battery 122, connected to terminals 156 and 158. In order to detect circuit failure on breadboard 104, solderboard 106, the H.A.T.T. device 102 can employ a thermistor array, connected via 128. This array detects overheating of components, and allows evasive action to be taken by means of automatically changing trace geometry, to other redundant components on the breadboard 104, solderboard 106. In the same manner, other signals, such as connection 130, a multimeter signal input, and 132, a digital oscilloscope input can be employed to check circuitry on breadboard 104, solderboard 106, to test if the circuit and components are working properly, and take action by reconfiguring trace geometry as needed. Connection 136 is a “Help” button input to H.A.T.T. device 102, from the circuit on breadboard 104, solderboard 106, which is pressed by user to initiate a process of self-analysis to fix any problems on said circuit, or H.A.T.T. device 102. Connection 138 is an output to power on the circuit on breadboard 104, solderboard 106, after trace geometry has been completely configured. Connection 140 is both an output to and input from breadboard 104, solderboard 106, to turn off the circuit residing on the same, or to turn off the H.A.T.T. device 102, after the aforementioned circuit turns off. Input 142 is an error signal input, telling the H.A.T.T. device 102 that there is something wrong with the circuit residing on the breadboard 104, or solderboard 106.

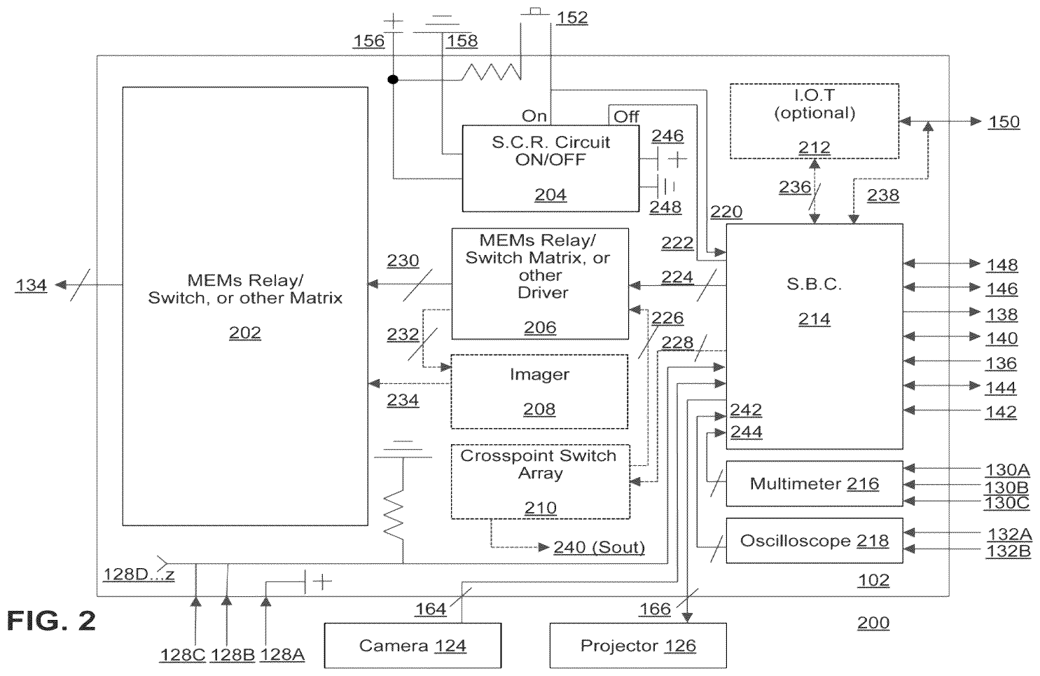

FIG. 2 illustrates a more detailed overview of the hardware employed to enable trace reconfiguration, as well as integrated test instruments. In FIG. 2, system 200 shows a single board computer (SBC) 214 which could be a Raspberry Pi 3B+ connected optionally via 236 to a Bolt Internet of Things (IoT) device 212, if the SBC 214 is not already configured as a Bolt I.O.T. The Bolt I.O.T. 212, or optionally the SBC 214, connects via 150, or optionally 238 and 150, wirelessly to Wi-Fi Router 114, then to the internet 118 and to web application 116. The SBC 214 connects via connection 224 to the Micro Electrical Machine (MEMs) relay or switch matrix driver 206, which in turn drives the MEMs relay/switch matrix 202 via connection 230. The trace geometry is then passed via connections 134 to the breadboard 104, or solderboard 106. Depending on the switch matrix 202 embodiments, a crosspoint switch array 210 such as AD75019 by Analog Devices, can be employed to enable individual chip drivers 206 attached to the switches in switch matrix 202, as in the case of MEMs chip (e.g., a CF24410 Cenfire switch array by Atomica, and the like). The crosspoint switch array 210 can connect to the SBC via connection 228, to the driver(s) via connection 226, and can be expanded to include a plurality of crosspoint switch arrays as necessary via connection 240. In an alternative embodiment, switch matrix 202 could be an F.P.G.A, or A.S.I.C. In another alternative embodiment of switch matrix 202, wherein the switches are photo-coupled, a driver 206, connected via 232 to an imager 208 can be employed to draw traces with light under the photo-coupled switches via connection 234, thereby activating the switch matrix 202 where the light from the imager 208 illuminates the individual photodetectors, to create trace geometry. The imager 208 can be LCD, DLP, LCOS, DMD, LED, OLED, or other video technology. In the same vein, the photo-coupled switches and imager could be implemented on a silicon optical bench. A Silicon-Controlled Rectifier (SCR) circuit 204 turns the H.A.T.T. device 102 on or off, via switch 152, or connection 220 or 222. The load of H.A.T.T. device 102 can be sourced by connections 246 and 248. Pressing button 152 once turns the H.A.T.T. device 102 on, and pressing it twice sends a signal to SBC 214 through connection 220, to first turn off the circuit on breadboard 104, or solderboard 106, if one exists, via connection 140, then turn itself off via connection 222. A digital multimeter 216 can be employed via connection 244 to SBC 214 to test voltage, current, conductance, resistance, capacitance, inductance, and whether a transistor, SCR or diode on the breadboard 104, or solderboard 106 circuit is good or bad. A digital oscilloscope 218 can be employed via connection 242 to SBC 214 to test the signals on a circuit on breadboard 104, or solderboard 106.

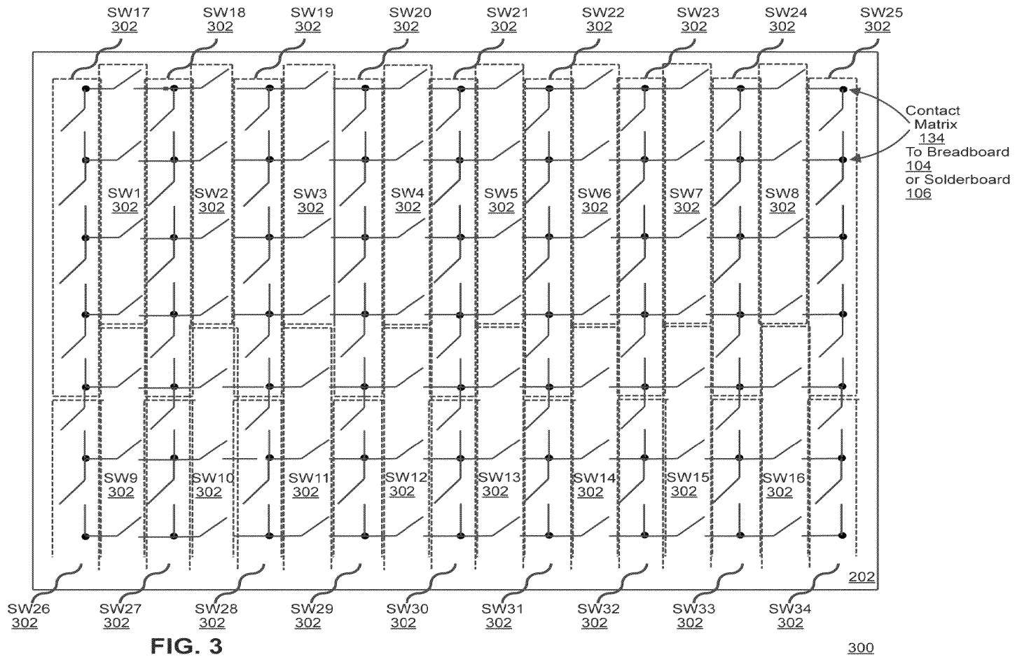

FIG. 3 illustrates the switching matrix employed to enable the trace geometries on the smart breadboard or smart printed circuit board. In FIG. 3, system 300 shows an array of switches inside switching matrix 202 including switch 302 in an advantageous configuration, such that when closed, trace geometries are formed between contact matrix connections 134, on the breadboard 104, or solderboard 106. Trace geometries can be made in the x and y directions like a two-dimensional Cartesian coordinate system. Diagonal traces can be made by switching alternately vertically and horizontally, such as in a “staircase” fashion. The smaller the switch 302, the denser the contact matrix connections 134, which result in more possible traces per square inch of breadboard 104, or solderboard 106. In order to make the switch array, and by extension the breadboard 104 or solderboard 106 contact matrix 134 denser, a silicon optical bench can be used, along with Through Silicon Vias (TSV) and Silicon Interposers. Switch 302 is shown as a four-switch discrete MEMs chip (e.g., a CF24410 Cenfire switch array by Atomica, and the like). This chip was selected for its bi-directional nature, small size, low resistance, and low parasitic capacitance-traits necessary for a smart breadboard to work. However, other switch embodiments can be made into a suitable array for breadboard 104, or solderboard 106, as discussed in the description of FIG. 2, with similar advantageous traits.

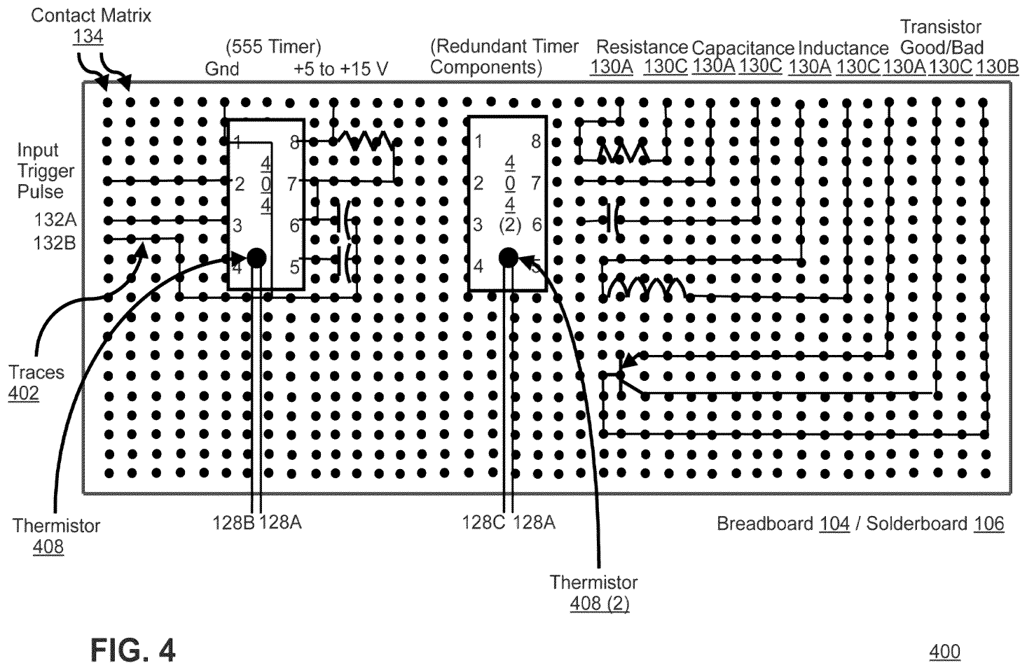

FIG. 4 is an illustrative view of the smart breadboard or smart printed circuit board, with components attached and connected via the generated reconfigurable traces. In FIG. 4, system 400 shows traces 402, between points on contact matrix 134, connecting a 555 timer chip 404 to capacitors and a resistor. An oscilloscope 218 receives a signal output from timer 404, connected via inputs 132A and 132B, to traces 402. Thermistors 408, 408 (2) sit on chip 404, 404 (2) respectively to output signals to the SBC 214, via connections 128B, 128A and 128C, 128A respectively. The thermistors are there to detect overheating of the chips 404, 404 (2). A redundant timer chip 404 (2) can be placed in case chip 404 overheats. In this case, chip 404 would be disconnected by the reconfigurable traces 402 and chip 404 (2) would be connected to take its place by other traces 402. Multimeter 216 can also be connected to the circuit on breadboard 104, or solderboard 106, via 130A, 130C and 130B to traces 402, connecting one at a time each to a resistor, capacitor, inductor, transistor, to measure resistance, capacitance, inductance, or whether a transistor is still working, respectively. Multimeter 216 can also connect via 130A, 130C to traces 402 to measure conductance, voltage, current, or whether a diode or SCR works.

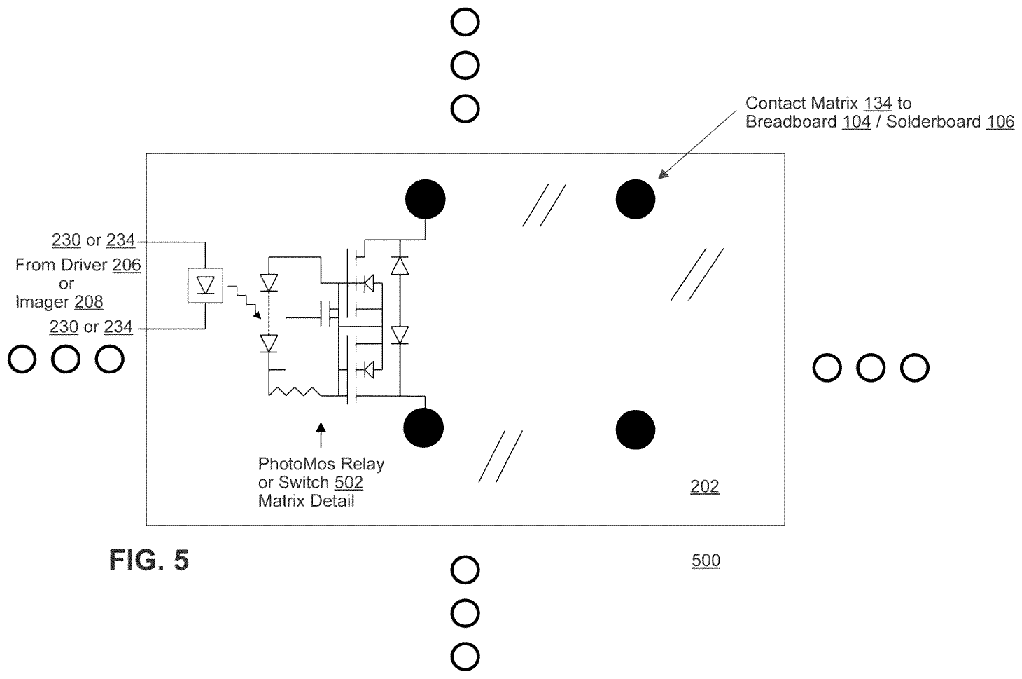

FIG. 5 illustrates an example of another embodiment of the switching matrix, using PhotoMOS technology. In FIG. 5, system 500 shows a PhotoMOS relay or switch 502, connected to the contact matrix 134. This switch 502 can be driven by a driver 206, via connection 230, or alternatively via the light output of an imager 208, connection 234.

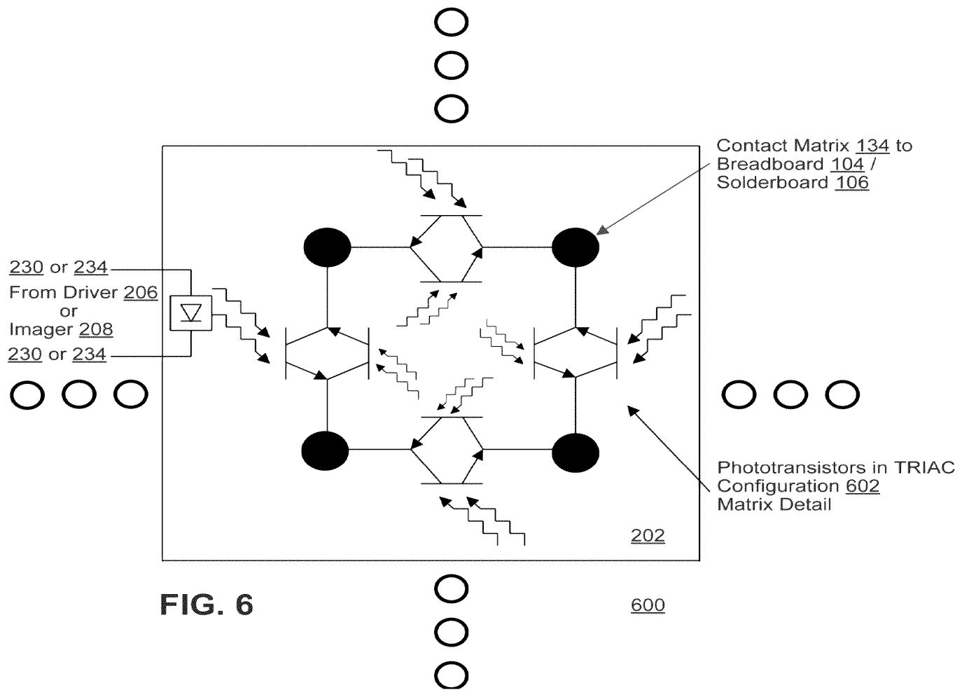

FIG. 6 illustrates an example of another embodiment of the switching matrix, using phototransistors in a TRIAC configuration. In FIG. 6, system 600 shows a phototransistor TRIAC switch 602, connected to the contact matrix 134. This switch 602 can be driven by a driver 206, via connection 230, or alternatively via the light output of an imager 208, connection 234.

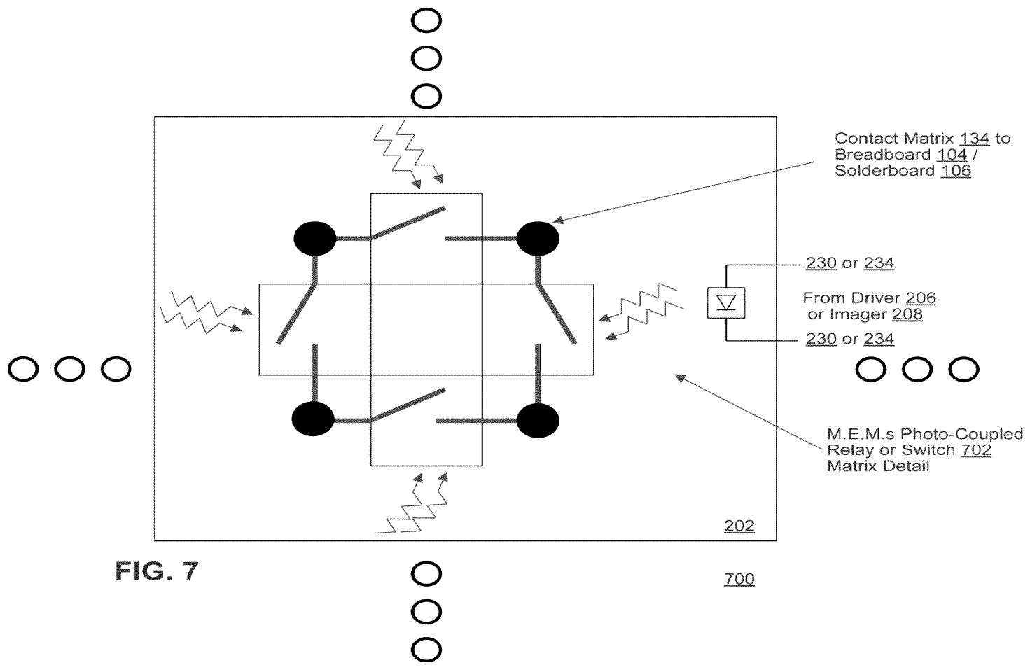

FIG. 7 illustrates an example of another embodiment of the switching matrix, using a MEMs photo-coupled relay or switch. In FIG. 7, system 700 shows a MEMs photo-coupled relay or switch 702, connected to the contact matrix 134. This switch 702 can be driven by a driver 206, via connection 230, or alternatively via the light output of an imager 208, connection 234.

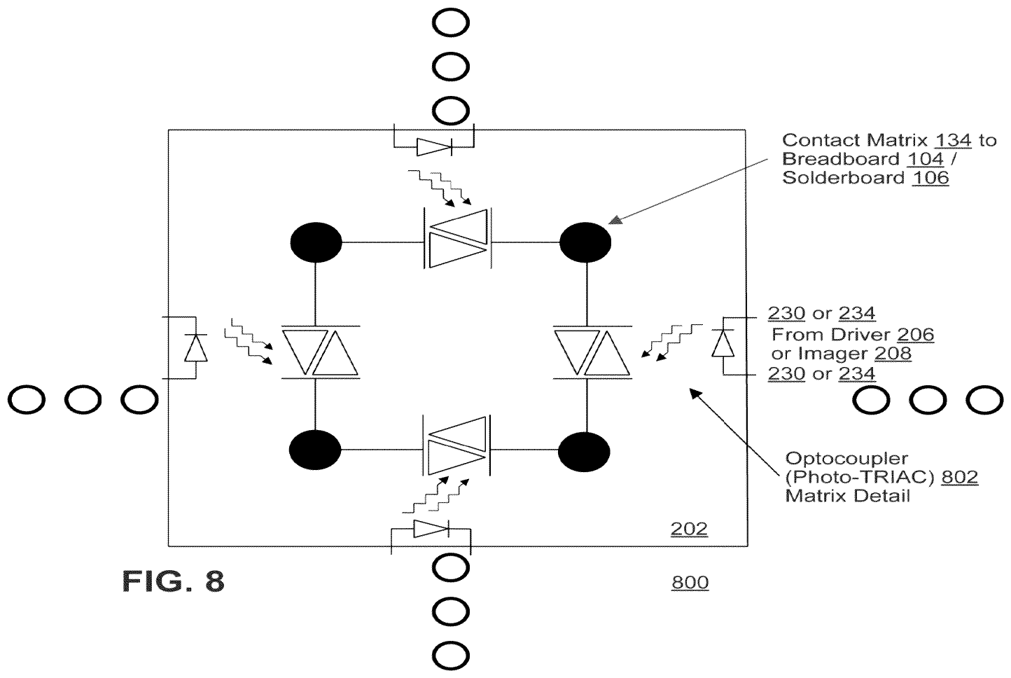

FIG. 8 illustrates an example of another embodiment of the switching matrix, using an optocoupler or photo-TRIAC. In FIG. 8, system 800 shows an optocoupler 802, connected to the contact matrix 134. This switch 802 can be driven by a driver 206, via connection 230, or alternatively via the light output of an imager 208, connection 234.

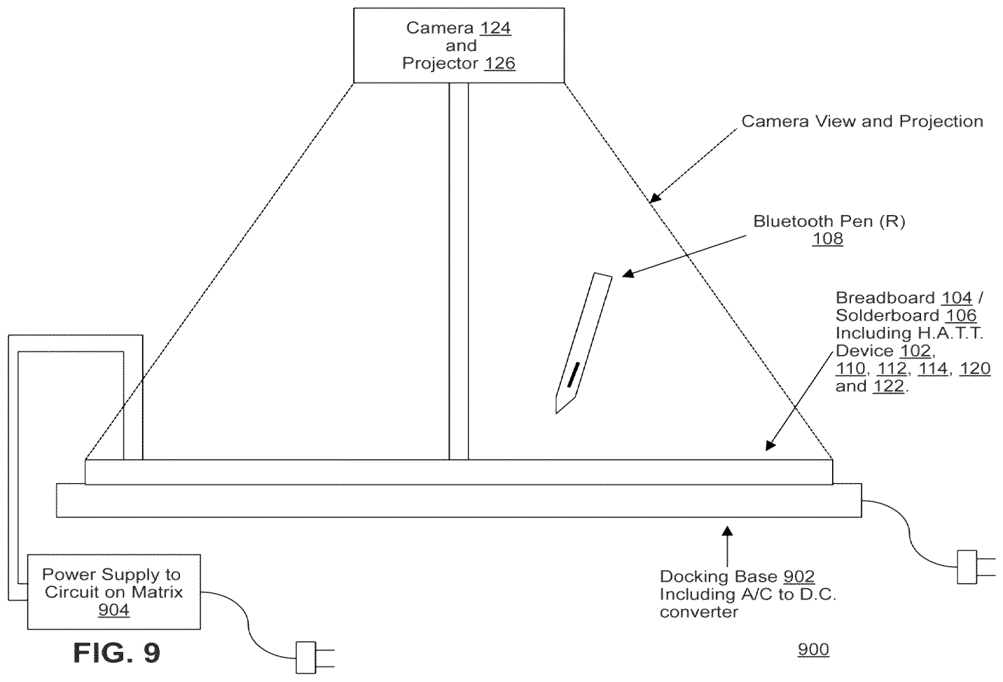

FIG. 9 illustrates the workbench configuration used to design circuitry employing the smart breadboard or smart printed circuit board. In FIG. 9, system 900 shows docking base 902, which includes an alternating current (AC)/direct current (DC) converter to power the H.A.T.T. device system 100, and a support and attachment for the camera 124 and projector 126. A separate power supply 904 can be used to power the circuit on the breadboard 104, or solderboard 106.

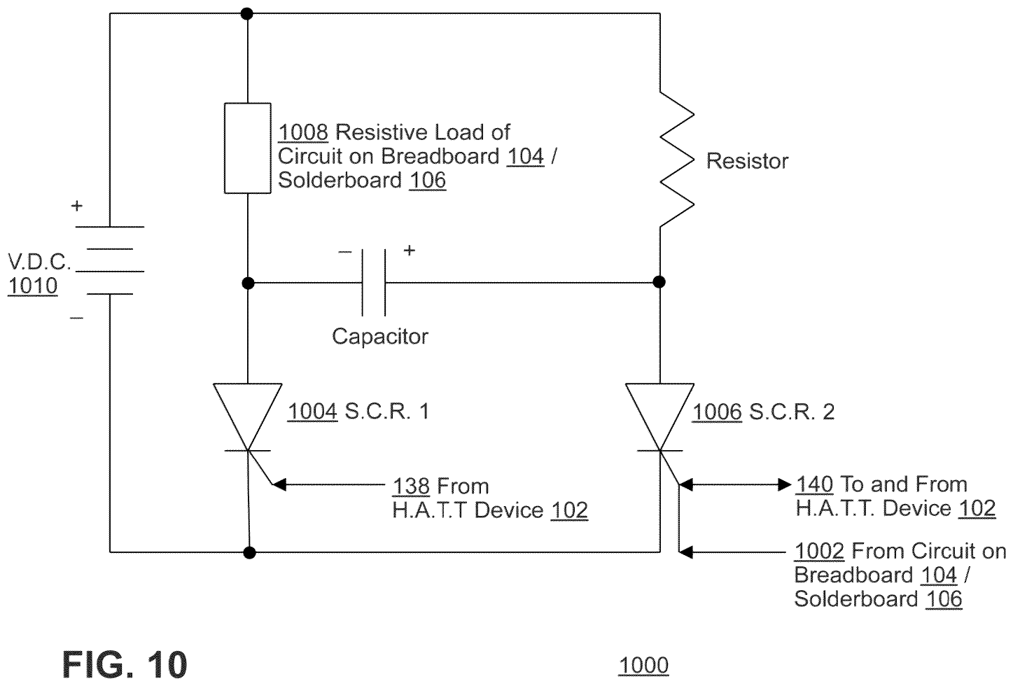

FIG. 10 illustrates an example of a circuit implemented on the smart breadboard to turn on/off the circuit on the breadboard, by the smart breadboard, or alternatively turn off the smart breadboard by the circuit on the smart breadboard. In FIG. 10, system 1000 shows connection 1002 from the circuit on breadboard 104, or solderboard 106, which both turns off SCR 1006, and by extension the load of the circuit 1008, and signals to H.A.T.T. device 102 to turn off, via connection 140. The H.A.T.T. device 102 can also send a signal via 140 to turn off SCR 1006, which turns off the power to the circuit load 1008. SCR 1004 can be triggered by connection 138, from H.A.T.T. device 102, to turn power on to the circuit load 1008. In any case, power to the H.A.T.T. device 102 should be turned on first, to configure the switch matrix 202, to configure the contact matrix 134, setting the circuit trace geometry 402 before the circuit load 1008 turns on. Power V.D.C. 1010 to the circuit on breadboard 104 or solderboard 106 can come from power supply 904, or a battery.

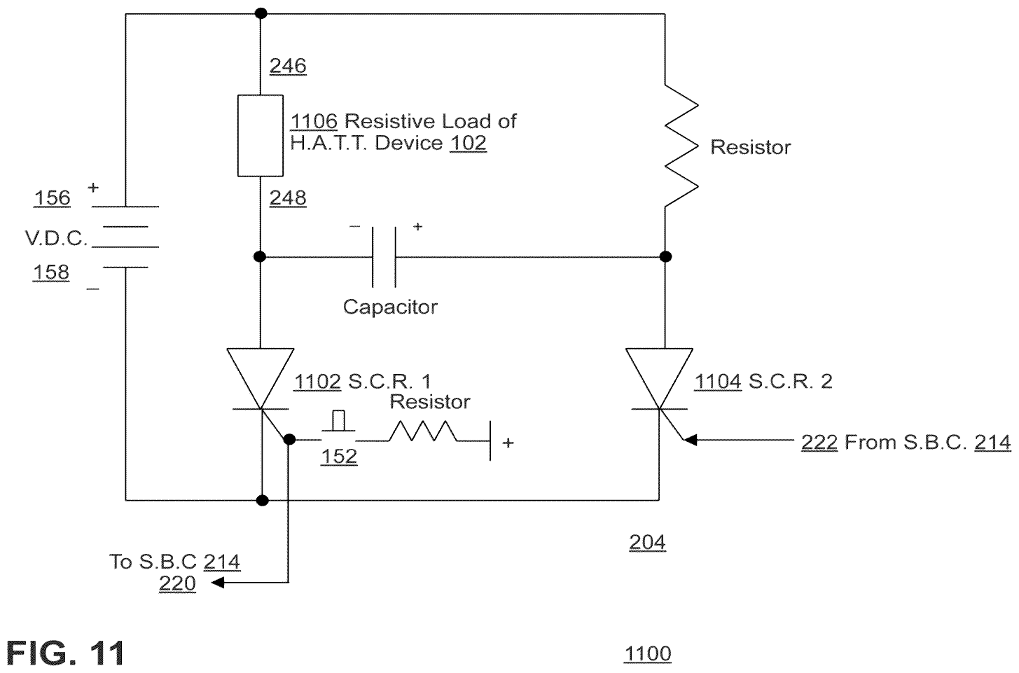

FIG. 11 illustrates an example of a circuit within the smart breadboard to power it on, or power it off. In FIG. 11, system 1100 shows SCR 1102 which can be turned on manually by Switch 152, which turns on the load 1106 of H.A.T.T. device 102, by connections 246 and 248. A signal from SBC 214 via connection 222 to S.C.R 1104 turns off the H.A.T.T. device 102. Pressing button 152 once turns the H.A.T.T. device 102 on by triggering SCR 1102, and pressing it twice sends a signal to SBC 214 through connection 220, to first turn off the circuit on breadboard 104 or solderboard 106, if one exists, via connection 140, then turn itself off via connection 222 which triggers SCR 1104, turning off load 1106, the H.A.T.T. device 102. The proper shutdown sequence is to first shut down the circuit on breadboard 104, or solderboard 106, if once exists, then the H.A.T.T. device 102, which begets the trace geometry 402 on which the circuit sits.

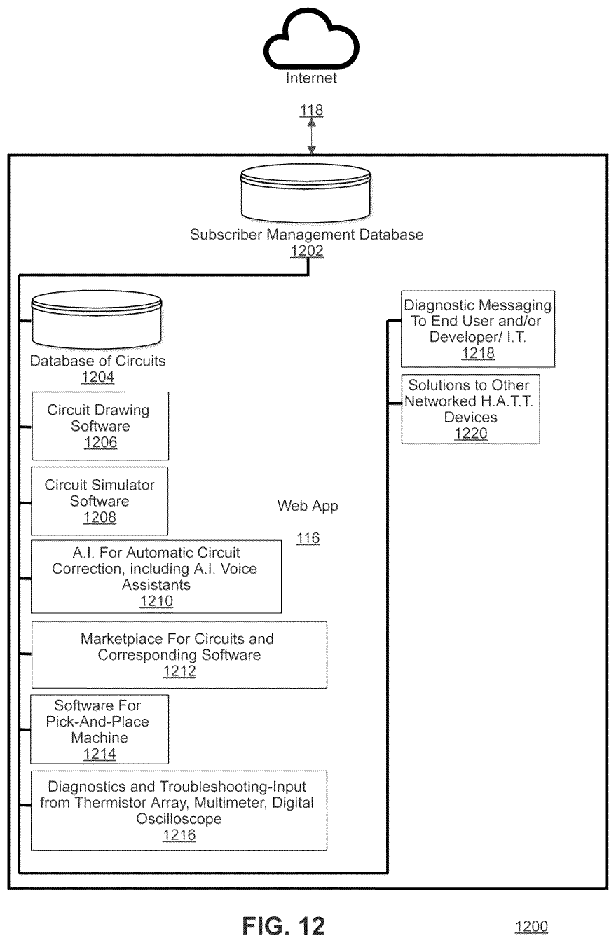

FIG. 12 illustrates a concept of a web application which supports the smart breadboard or smart printed circuit board as an IoT (Internet of Things) with several software functions. In FIG. 12, system 1200 shows a subscriber management database 1202, in web application 116, connected to the internet 118. The subscriber management database 1202 holds all user credentials to access each particular H.A.T.T. device system 100 associated with the user, via username and password. Each subscriber can have access to a database of circuits 1204, which includes circuits developed or acquired by the user. The subscriber also can have access to circuit drawing software 1206, to design trace geometries 402 using a computer interface, or Bluetooth pen 108 directly on the breadboard 104, or solderboard 106. Circuit drawing software 1206 can also show discrete components. To aid in circuit design and component placement on breadboard 104 or solderboard 106, a camera 124 and Projector 126 can be employed, which aid drawing software 1206 to identify discrete components automatically and suggest trace 402 placement, by showing the suggested traces 402 on the computer or by projection 126 on the breadboard 104, or solderboard 106. In photo-coupled embodiments of switch matrix 202, using imager 208, circuit drawing software 1206 can have the option of drawing variable light intensity optical traces, which allow for more or less current/voltage flow in the traces 402. Circuit drawing software 1206 can also output trace design like a Gerber file to create trace geometry 402 onto a regular printed circuit board (PCB). Circuit simulator software 1208 can aid in the design of the real circuit on breadboard 104, or solderboard 106. In photo-coupled embodiments of switch matrix 202, circuit simulator software 1208 can suggest the intensity of light in Imager 208 optical traces to obtain the correct current/voltage flow for traces 402. Advantageously, Artificial Intelligence (AI), which can employ AI Voice Assistants, 1210, can be used for saving time in circuit design or for troubleshooting and correcting finished circuits. Each subscriber in system 1200 also can have access to a marketplace for circuits and corresponding software 1212. In the marketplace 1212, users can purchase or acquire freely trace geometries 402 to download into the database of circuits 1204, and download to H.A.T.T. device system 100, for use on the breadboard 104 or solderboard 106. The acquired trace geometries 402 can be bundled with information about used components to display on circuit drawing software 1206 or circuit simulator software 1208. The acquired trace geometries 402 can also be bundled with corresponding software for the circuit to be placed on breadboard 104, or solderboard 106. The acquired trace geometries 402 can also be bundled with information for a pick-and-place machine. Software for a pick-and-place machine 1214 can also be employed to easily place components onto the smart solderboard 106. Notice that no traces need to be routed, only components placed on a smart solderboard 106, since trace geometry 402 is handled by the integrated H.A.T.T. device system 100. Diagnostics and troubleshooting 1216 can be implemented in system 1200, wherein input connections 128 from a thermistor array, input connections 130 from a multimeter 216, input connections 132 from an oscilloscope 218, “Help” signal input 136, and error signal input 142 are uploaded in real time to web application 116, for visualization of their data, and to commence troubleshooting and diagnostics. Diagnostic messaging 1218 can also be implemented in system 1200, to send error messages or updates to either the end user, developer, I.T. technician or all three. In case there are updated solutions to errors found in the H.A.T.T. system 100 or the circuit it supports on breadboard 104, or solderboard 106, system 1200 can provide solutions to other, similar networked H.A.T.T. devices 1220, across other subscriber accounts in subscriber management database 1202.

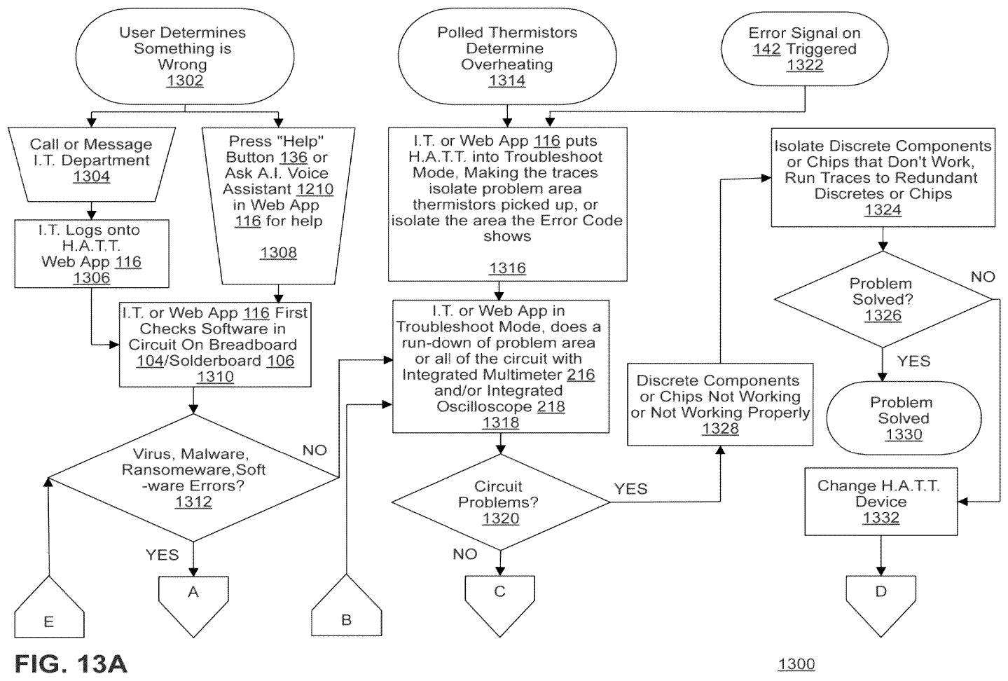

FIG. 13A-13B illustrates an example of the software logic which determines how to fix the circuit on the smart breadboard using reconfigurable traces and integrated test and measurement devices, when something is wrong with said circuit on the smart breadboard or smart PCB. In FIG. 13A-13B, system 1300 shows three entry points to detecting system instability. The first, user determines something is wrong, 1302, with the entire device. The user then manually calls or messages the I.T. department 1304, which then logs into the web app 116, 1306, or the user presses the “Help” button 136, or asks the voice assistant 1210 in web application 116, for help, 1308. Both methods lead to 1310, wherein the I.T. department or web app 116 can first check the software in the circuit on breadboard 104 or solderboard 106. A decision is made whether there are virus, malware, ransomeware or software errors 1312. If YES, then use a software fix 1334 to fix the problem. Is the problem fixed, 1336? If YES, then the problem is solved 1338; The solution is logged into web app 116, in software 1216, updated in database of circuits 1204, and can be sent to other networked H.A.T.T. devices 1220. If NO to either 1312 or 1336, then process 1318 is invoked. Process 1318 involves having I.T. user or web app 116 through software 1216 put the H.A.T.T. device system 100 in troubleshoot mode which does a run-down of the problem area or all of the circuit on breadboard 104, or solderboard 106, with multimeter 216 and/or oscilloscope 218. A decision 1320 is made. Are there any circuit Problems? If NO, then there is a diagnosis of a possible software error in the circuit on breadboard 104, or solderboard 106, 1340, which then leads to decision 1312 again. Are there any virus, malware, ransomware, or software errors? This leads to a loop, until the problem is solved, 1338. If decision 1320 determines YES, there are circuit problems, the diagnosis 1328 is that discrete components or chips are not working, or not working properly, which leads to process 1324. Process 1324 isolates discrete components or chips that don't work, and runs traces to redundant discrete components or chips. Decision 1326 is made. Are the problems solved? If YES, then the problem is solved, 1330; The solution is logged into web app 116, in software 1216, updated in database of circuits 1204, and can be sent to other networked H.A.T.T. devices 1220. If NO, then invoke process 1332, which is to change the H.A.T.T. device system 100. Decision 1342 is reached. Is the problem solved 1342? If YES, then the problem is solved 1338; The solution is logged into web app 116, in software 1216, updated in database of circuits 1204, and can be sent to other networked H.A.T.T. devices 1220. If NO, then change the circuit on breadboard 104, or solderboard 106, 1344; The solution is logged into web app 116, in software 1216, updated in database of circuits 1204, and can be sent to other networked H.A.T.T. devices 1220. The second and third entry points to detecting system instability are that polled thermistors determine overheating 1314, and an error signal on 142 is triggered, 1322. Both these logical entry points coalesce to process 1316. Process 1316 involves having the I.T. user or web app 116 put the H.A.T.T. device 102 in troubleshoot mode, making traces 402 isolate the problem area thermistors detected, or isolate the area on breadboard 104, or solderboard 106 shown by the error signal on 142. This process is followed by process 1318, and the rest of the flowchart as previously mentioned.

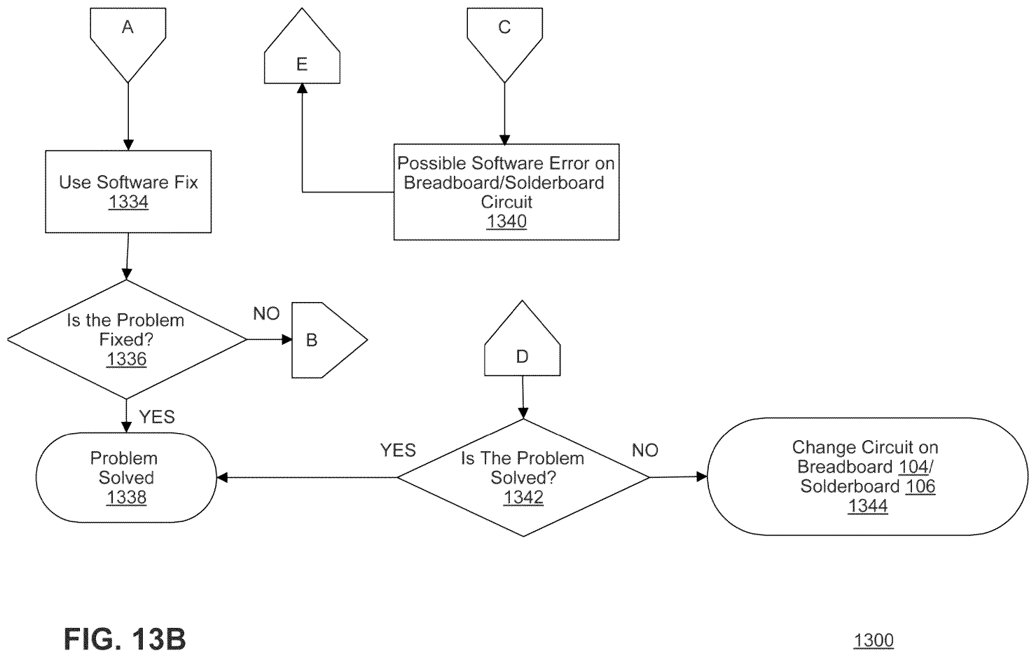

FIG. 14 is an illustrative representation of a proof-of-concept prototype for a magnetically induced conductivity system, which can be used as a Bipolar Magnetic Field Effect Transistor (MFET) utilizing a steel powder layer and a movable magnet. In FIG. 14, the prototype 1400 features copper shielding 1402 that symbolizes the tie points or contact points on a reconfigurable circuit board. A layer of steel powder 1404 (e.g., S100N mesh 100) is sandwiched between two glass plates 1406 (e.g., borosilicate glass), which provide structural support and help contain the steel powder. A magnet 1408 (e.g., rare earth neodymium N50) is positioned above the steel powder layer, and it can be moved between an “ON” position 1414, where it aligns with the steel powder, and an “OFF” position 1412, where it is moved away. When the magnet 1408 is in the “ON” position 1414, the magnetic field compresses the steel powder 1404, making it electrically conductive and allowing current to flow through the copper shielding 1402. Conversely, when the magnet is in the “OFF” position 1412, the steel powder becomes non-conductive, effectively turning off the circuit. The electrical conductivity of the system is measured by a conductivity meter 1410 connected to the circuit, which monitors the state of the steel powder 1404. The prototype is demonstrated with two microscopy images, one showing the steel powder in a magnetized state 1416, where the particles are aligned and conductive, and the other showing the steel powder in a demagnetized state 1418, where the particles are unaligned and non-conductive. This configuration can serve as the basis for a reconfigurable circuit element that operates based on magnetic fields rather than traditional electrical signals, offering a novel approach to circuit design and potential applications in dynamically reconfigurable electronics.

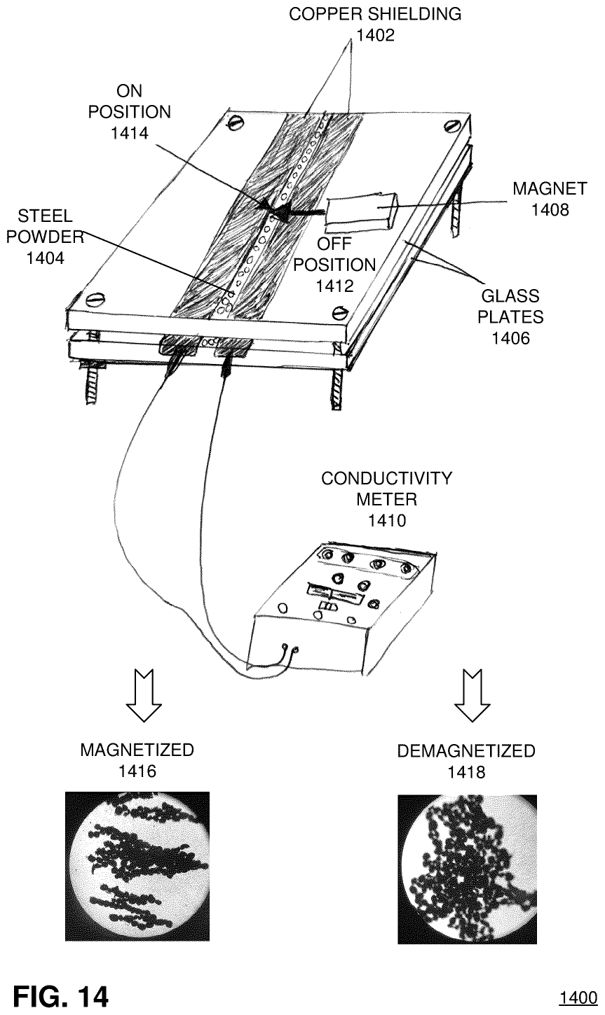

FIG. 15 is an illustrative depiction of a magnetically controlled conductive path formation system, utilizing programmed magnetic domains and steel powder to create or disrupt electrical conductivity. In FIG. 15, the system 1500 includes a steel plate or substrate containing programmed magnetic domains 1502, which are regions where the magnetic field has been specifically configured to create a desired magnetic pattern. These programmed magnetic domains 1502 are used to control the alignment and compression of steel powder 1504 placed above or within the magnetic field. When the steel powder 1504 is subjected to the influence of these magnetic domains 1502, the particles of the steel powder 1504 align and compress, forming electrically conductive pathways. These conductive pathways can be precisely controlled by the pattern of the magnetic domains 1502, allowing for the dynamic creation or disruption of circuit paths based on the presence or absence of a magnetic field. The side view 1506 of the system shows the relative thickness of the steel powder layer, indicating how the powder is distributed in relation to the magnetic domains. The system 1500 makes use of S100N steel powder 1508, which is finely ground to ensure that it responds effectively to the magnetic fields generated by the programmed domains. The S100N steel powder 1508 can be compressed into dense, conductive paths when subjected to the magnetic fields, while it remains non-conductive when the fields are inactive or not aligned. The programmable nature of the magnetic domains allows for flexible and reconfigurable circuit designs, which can be adapted for various electronic applications where dynamic control of conductivity is advantageous.

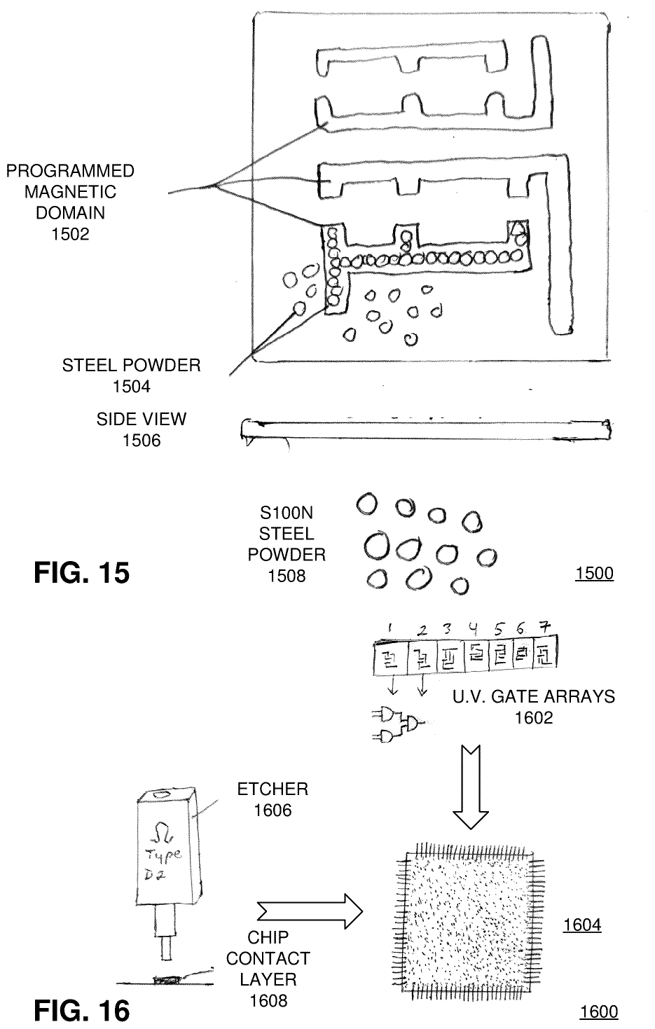

FIG. 16 is an illustrative depiction of a manufacturing process for creating a chip with optically controlled gate arrays using UV light exposure on a photoconductive layer. In FIG. 16, the system 1600 includes a chip contact layer 1608, which serves as the substrate where electrical contacts are formed. The process begins with the use of a Simmon Omega D2 Enlarger 1606, which is employed in reverse to reduce the image size of the circuit patterns down to angstrom levels. This reduction is achieved via photo-etching or photo-resist techniques, allowing for the precise creation of contact points on the chip contact layer 1608, which is made of copper. The UV gate arrays 1602, represented as a series of gate patterns, are then projected onto the chip contact layer 1608 using a UV light source, such as a laser, and the like, (see, e.g., Wang et al., “Photonic-circuit-integrated titanium: sapphire laser,” Nat. Photon. 17, 338-345, 26 Jan. 2023, incorporated by reference herein). These UV gate arrays 1602 define the circuit pathways on the chip by selectively exposing regions of the contact layer to ultraviolet light, which modifies the photoconductive properties of the material. The photoconductive layer on the chip 1604 is made from ZnO photoconductive powder interspersed on top of the contact layer, which touches each contact point and responds to UV light to either make or break electrical contacts dynamically. An etcher 1606, such as the Type D2 etcher shown, is used to etch fine patterns into the chip contact layer 1608 after it has been exposed to the UV light. The etching process removes unexposed areas of the photoconductive material, leaving behind a precise pattern of conductive pathways that correspond to the UV gate arrays 1602. The chip contact layer 1608 is then developed to reveal the final circuit design, with conductive pathways formed where the material was exposed to UV light. The UV light interacts with the photoconductive material on chip 1604, altering its electrical properties to establish or disrupt connections within the chip. This method allows for the creation of complex circuits at very small scales, with the UV gate arrays 1602 enabling the selective control of gate formation. The chip can mimic any ASIC chip without requiring traditional programming, offering infinite applications. It functions by running sequences of UV light images controlled by A.I., which dynamically create or erase gates on the chip, allowing it to emulate any fixed-trace design or function as a neuromorphic A.I. processor. This process is particularly suited for applications requiring high precision and the ability to reconfigure circuits on a microscopic scale, leveraging photolithography techniques to achieve fine detail in chip manufacturing.

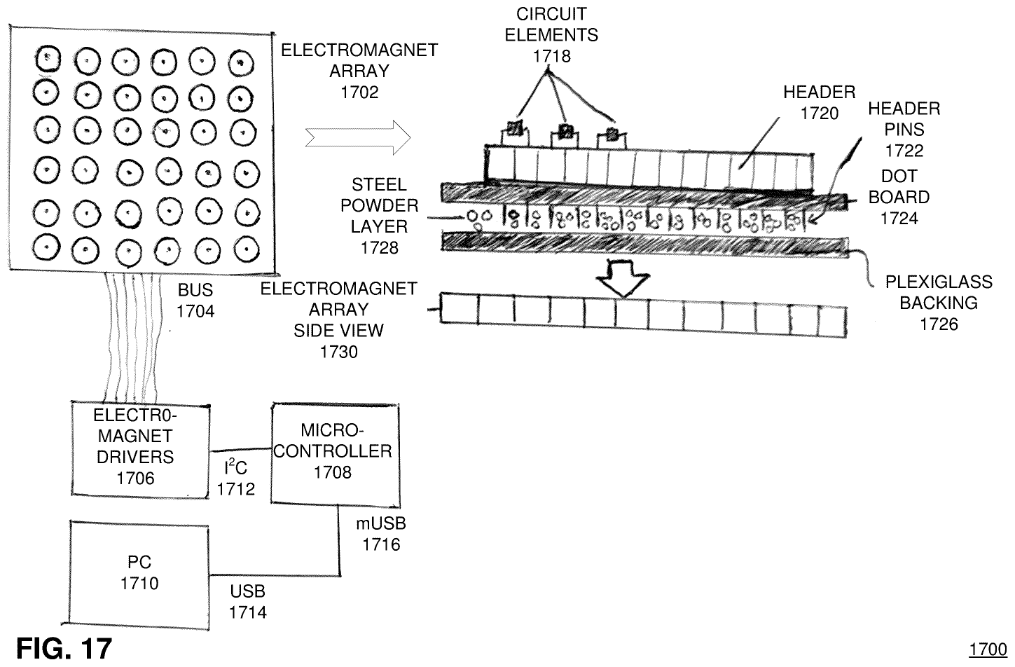

FIG. 17 is an illustrative depiction of a reconfigurable circuit system that utilizes an electromagnet array to manipulate a steel powder layer, enabling dynamic circuit configuration. In FIG. 17, the system 1700 can include a grid of electromagnets 1702, which can be individually controlled to influence the alignment of a steel powder layer 1728 placed above it. The steel powder, likely a material such as S100N, becomes conductive when aligned by the magnetic fields generated by the activated electromagnets, allowing for the creation or modification of circuit pathways within the steel powder layer. The circuit elements 1718, which include discrete electronic components or chips, are placed on top of a dot board 1724 and interact with the reconfigurable circuit paths formed in the steel powder layer. The dot board 1724 is designed with through-holes and plated barrels to securely mount components and ensure electrical connections. The entire assembly is supported by a plexiglass backing 1726, which provides structural stability and transparency, allowing visibility of the internal layers. Header 1720 and header pins 1722 connect the circuit elements on the dot board to external circuits or systems, facilitating input/output and power connections. The electromagnet array 1702 is controlled by electromagnet drivers 1706, which manage the power supply to each electromagnet based on instructions received from a microcontroller 1708. The microcontroller 1708 interfaces with a PC 1710, which serves as the main control hub. The PC runs software that sends commands to the microcontroller, allowing for real-time control and manipulation of the electromagnet array. Communication between the components is facilitated by a bus 1704, which connects the electromagnet drivers to the microcontroller, as well as an I²C interface 1712 and USB connections 1714 and 1716 for data exchange between the PC, microcontroller, and electromagnet drivers. The electromagnet array side view 1730 provides a vertical perspective, showing the alignment of the electromagnets relative to the steel powder layer. This configuration allows for real-time, on-the-fly reconfiguration of the circuit paths without the need for physical rewiring, making the system a versatile tool for prototyping, adaptive circuit development, and potential applications in reconfigurable computing or neuromorphic processors.

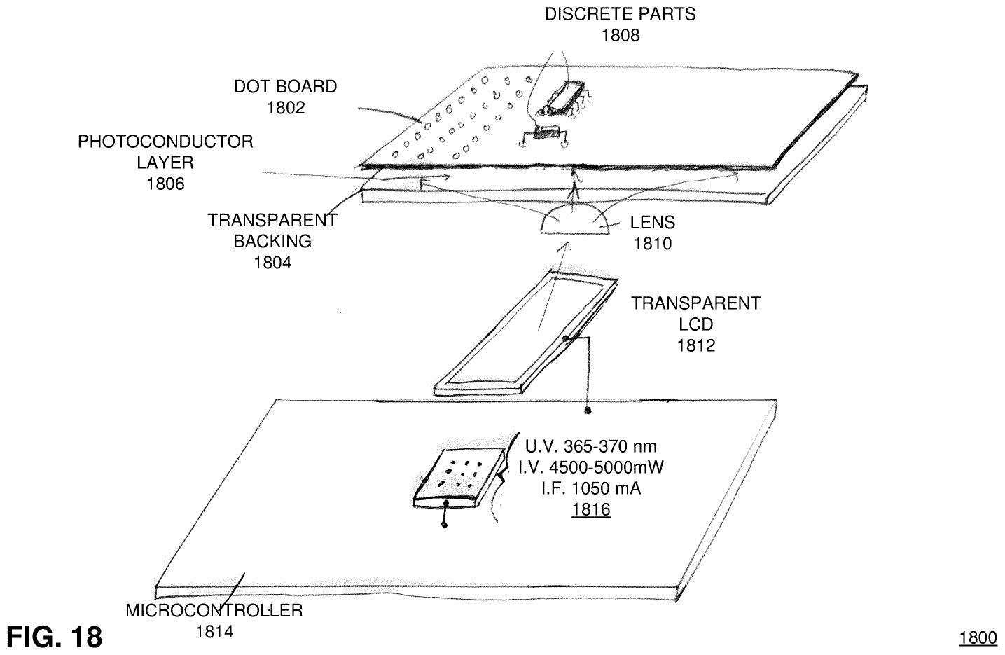

FIG. 18 is an illustrative representation of a reconfigurable photonic circuit system that can utilize a combination of UV light, a photoconductor layer, and a transparent LCD to dynamically alter circuit configurations with high precision. In FIG. 18, the system 1800 includes a dot board 1802 designed for mounting discrete parts 1808, such as chips or other electronic components, which are advantageous to the circuit's functionality. These components interface with a photoconductor layer 1806, composed of materials like Zinc Oxide (ZnO), which has photoconductive properties that respond to UV light, potentially altering the electrical conductivity of the circuit paths. The photoconductor layer 1806 is supported by a transparent backing 1804, ensuring structural integrity while allowing the UV light to pass through efficiently. The lens 1810 can focus the UV light emitted by the transparent LCD 1812 onto the photoconductor layer, helping ensure that the light interacts effectively with the circuit pattern displayed on the LCD. This transparent LCD 1812 can display a negative image of the circuit design, allowing the UV light to project a positive pattern onto the photoconductor layer 1806. The entire process can be managed by a microcontroller 1814, which controls the sequence and intensity of the UV light source 1816 (see, e.g., Wang et al., “Photonic-circuit-integrated titanium: sapphire laser,” Nat. Photon. 17, 338-345, 26 Jan. 2023, incorporated by reference herein). The UV light source operates at a wavelength range of 365-370 nm, with an intensity of 4500-5000 mW and a forward current of 1050 mA, parameters that can be advantageous in activating the photoconductor layer and achieving the desired reconfigurable circuit paths. This configuration allows for the dynamic creation, alteration, or erasure of circuit paths, depending on the real-time processing needs of the system, which presents an advancement in photonic circuitry and reconfigurable electronics.

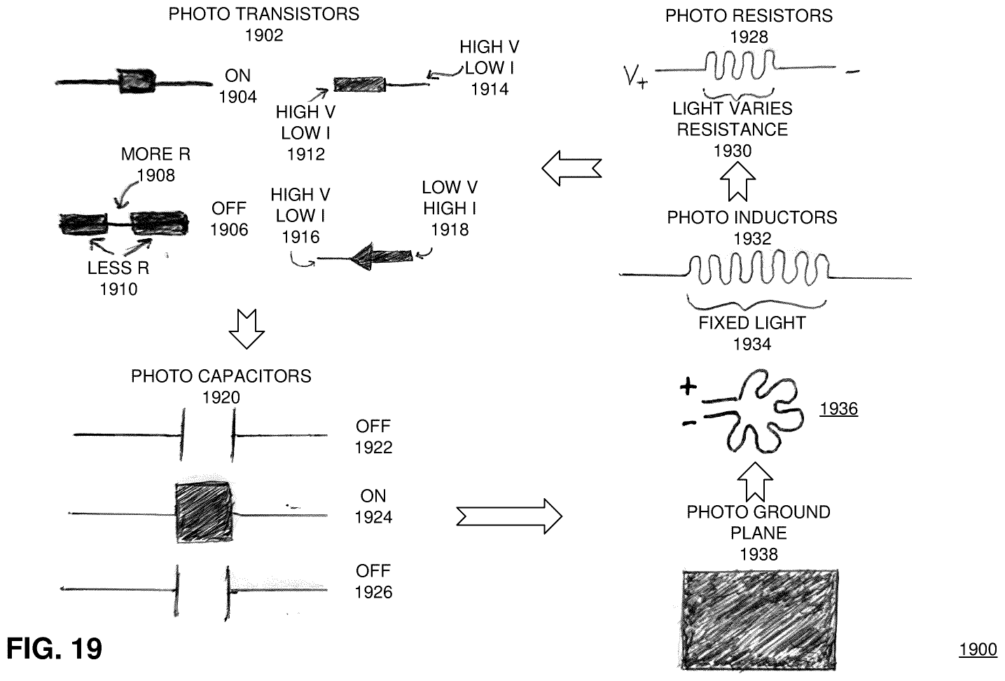

FIG. 19 is an illustrative representation of a dynamic light-responsive circuit system, showcasing various components such as photo transistors, photo resistors, photo inductors, photo capacitors, and a photo ground plane. In FIG. 19, the system 1900 can include photo transistors 1902, which can switch between “ON” 1904 and “OFF” 1906 states based on light intensity. The resistance of the photo transistors can be modulated by light, with more resistance 1908 or less resistance 1910 depending on the light conditions. The voltage and current behavior of the photo transistors can vary, providing a high voltage with low current 1912, 1914 or low voltage with high current 1916, 1918 based on the light exposure. Photo resistors 1928 can vary their resistance 1930 in response to light intensity, which directly influences the voltage across them. Photo inductors 1932 function similarly to traditional inductors but are influenced by light, with their behavior controlled by a fixed light source 1934. Photo capacitors 1920 can switch between OFF 1922, 1926 and ON 1924 states when exposed to light, functioning as traditional capacitors but with light as the control mechanism. The photo ground plane 1938 acts as a virtual ground plane within the circuit, represented by a symbol 1936, crucial for completing circuits and managing the flow of current. The components in FIG. 19 are designed to dynamically respond to light, allowing for reconfigurable circuit elements that can be adjusted based on light intensity, providing advanced control and flexibility in circuit design. This configuration enables the creation of circuits that can be dynamically reconfigured using light, making them suitable for flexible and adaptive circuit designs, particularly in neuromorphic and photonic computing systems where light serves as a primary control mechanism.

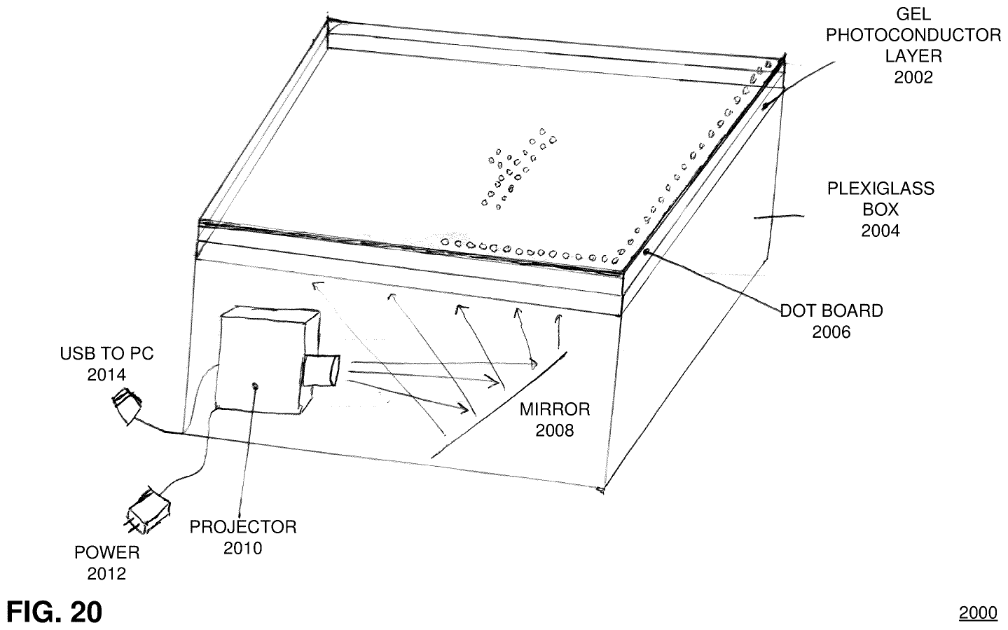

FIG. 20 is an illustrative system for reconfigurable circuit design housed within a plexiglass enclosure, where a dynamic interplay between light and a photoconductive gel layer facilitates real-time circuit reconfiguration. In. FIG. 20, the system 2000 includes a gel photoconductor layer 2002 applied on a dot board 2006 within a plexiglass box 2004. The gel photoconductor layer 2002, potentially composed of materials such as Zinc Oxide (ZnO) mixed with silicone or other stabilizing agents, changes its electrical conductivity when exposed to light. This gel layer, strategically placed on the dot board 2006, supports the formation of circuit paths that can be dynamically reconfigured by light exposure. The plexiglass box 2004 not only provides structural support but also serves as a transparent enclosure, allowing the internal components to be visually monitored while ensuring environmental protection. A mirror 2008 is integrated within the plexiglass box 2004 to direct and focus light from an external projector or laser 2010 (see, e.g., Wang et al., “Photonic-circuit-integrated titanium: sapphire laser,” Nat. Photon. 17, 338-345, 26 Jan. 2023, incorporated by reference herein) onto the gel photoconductor layer 2002 and the dot board 2006. The projector 2010, which emits light at a wavelength suitable for activating the photoconductive properties of the gel layer (e.g., UV light at 365-370 nm), is connected to a power source 2012 and interfaces with a PC 2014 via a USB connection 2014. This light source, likely a DLP (Digital Light Processing) projector, is capable of projecting precise light patterns, which, when reflected by the mirror 2008, create or modify circuit paths on the gel layer by altering its conductivity. The system's design allows for real-time control and reconfiguration of circuits through software running on the PC 2014, which can dynamically adjust the light patterns projected by the projector 2010 based on the desired circuit design. The reconfigurable nature of this system is further enhanced by the use of a dot board 2006, which may include through-holes and plated barrels for mounting discrete components or chips that interact with the photoconductive layer. This setup is highly advantageous for applications in adaptive electronics, prototyping, and neuromorphic computing, where circuits can be redefined and optimized on-the-fly without the need for physical alterations, making it a versatile platform for developing and testing new electronic designs.

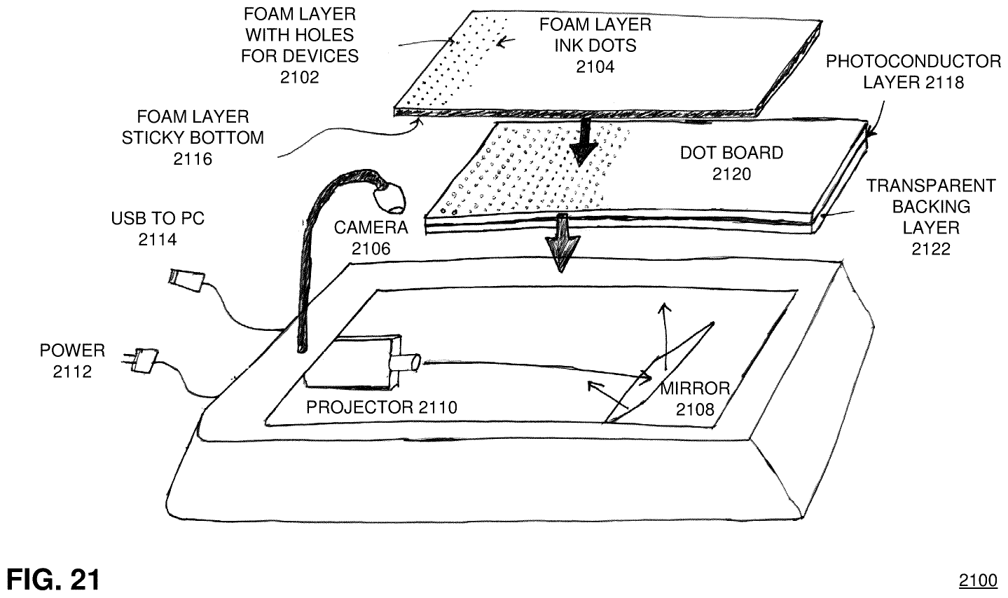

FIG. 21 is an illustrative system that showcases a layered assembly designed for reconfigurable circuit applications using light-responsive materials. In FIG. 21, the system 2100 can include a foam layer with holes for devices 2102, which allows for the precise placement of circuit components. The foam layer can be marked with ink dots 2104 to indicate the location of the through-holes, ensuring accurate alignment of components. Below the foam layer, a photoconductor layer 2118 is positioned, which can respond to light stimuli to alter its conductive properties, enabling dynamic circuit reconfiguration. The photoconductor layer is supported by a dot board 2120, which houses the electrical components and provides structural stability. The dot board is further backed by a transparent backing layer 2122 that adds support while allowing light to pass through. The system is equipped with a projector or laser 2110 (see, e.g., Wang et al., “Photonic-circuit-integrated titanium: sapphire laser,” Nat. Photon. 17, 338-345, 26 Jan. 2023, incorporated by reference herein) that directs light towards the photoconductor layer. The projector is supported by a mirror 2108 that reflects and focuses the light onto specific areas of the photoconductor layer, enabling precise control over circuit formation. A camera 2106 is included to monitor the system, providing real-time feedback that can be used to adjust the light patterns and optimize circuit performance. The projector and camera are connected to a power source 2112 and are interfaced with a computer via a USB connection 2114, allowing for high-level control and automation of the circuit reconfiguration process. The foam layer also includes a sticky bottom 2116, which helps secure the layer in place while allowing easy removal when adjustments are necessary. This system is designed for flexible and adaptable circuit design, making it suitable for rapid prototyping and dynamic electronic applications.

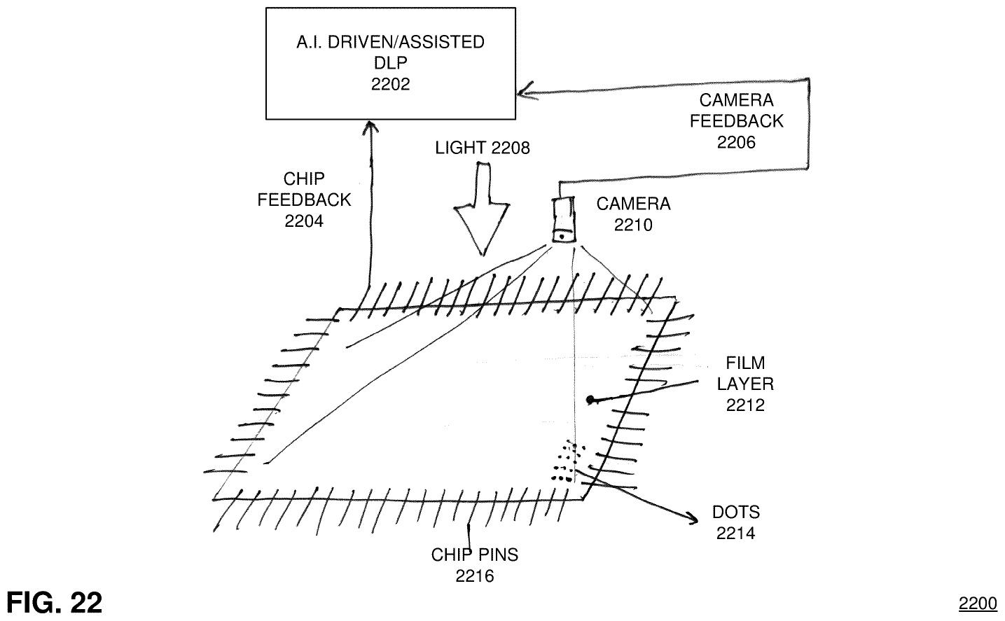

FIG. 22 is an illustrative representation of an A.I.-driven/assisted DLP system integrated with a dynamic photonic chip for real-time reconfigurable circuitry. In FIG. 22, the system 2200 includes an A.I.-driven/assisted DLP or laser 2202 (see, e.g., Wang et al., “Photonic-circuit-integrated titanium: sapphire laser,” Nat. Photon. 17, 338-345, 26 Jan. 2023, incorporated by reference herein) that projects light 2208, such as UV light with a wavelength around 365 nm, onto a film layer 2212 on a chip. This film layer 2212, potentially composed of Zinc Oxide (ZnO) or similar materials, is photoconductive and alters its electrical properties when exposed to light. The chip is embedded with chip pins 2216 and dots 2214 that form circuit connections. These dots 2214 could represent quantum dots, nanodots, or microdots, serving as critical points in the circuit configuration. The system is designed to allow the chip to be dynamically reconfigured through precise light patterns generated by the DLP 2202. The A.I. control in the DLP 2202 ensures the light patterns are optimized for real-time reconfiguration, potentially offering feedback mechanisms. Specifically, chip feedback 2204 provides real-time information about the chip's performance, while camera feedback 2206 from a camera 2210 ensures that the light patterns are correctly aligned and functioning as intended. This feedback loop is crucial for maintaining the accuracy and functionality of the circuit reconfigurations. The setup allows for the creation of highly adaptable and programmable photonic circuits, suitable for advanced applications such as neuromorphic processing, where circuits mimic neural structures, and dynamic circuit design. The transparency of the film layer 2212 to visible light, UV, and possibly infrared light also allows the system to monitor and detect thermal issues or other anomalies that could affect circuit performance, further enhancing its adaptability and resilience.

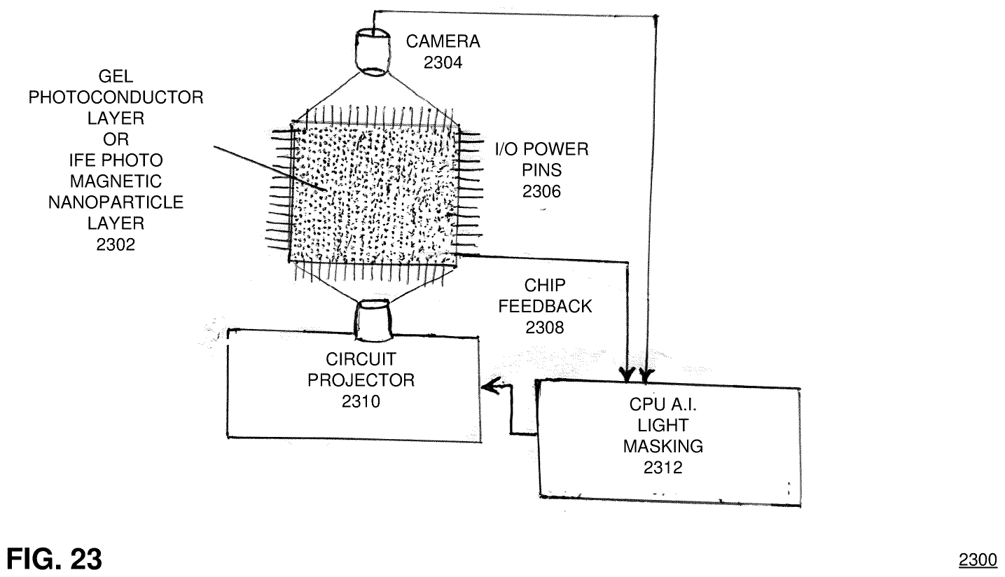

FIG. 23 illustrates a sophisticated system designed for dynamically reconfigurable circuitry using advanced materials and AI-driven controls. In FIG. 23, the system 2300 can include a layer 2302 that may consist of either a gel photoconductor or an Inverse Faraday Effect (IFE) photo magnetic nanoparticle layer, both of which are capable of altering their electrical properties in response to light or magnetic fields (see, e.g., Cheng et al., “Light-induced magnetism in plasmonic gold nanoparticles,” Nat. Photon. 14, 365, 16 Mar. 2020, incorporated by reference herein). The system is equipped with a camera 2304 that is strategically positioned above the chip to monitor the real-time status of the circuit configuration and operation. This camera 2304 continuously captures feedback from the circuit and sends this data to a central processing unit (CPU) 2312, which is integrated with AI capabilities to perform light masking—a process that involves selectively projecting light patterns to configure the circuit pathways. The I/O power pins 2306 serve as the interface between the reconfigurable circuit and external components or systems, allowing the circuit to interact with and control various electronic devices. This interconnection is vital for practical applications, enabling the system to be integrated into larger electronic frameworks. The circuit projector or laser 2310 (see, e.g., Wang et al., “Photonic-circuit-integrated titanium: sapphire laser,” Nat. Photon. 17, 338-345, 26 Jan. 2023, incorporated by reference herein) is an advantageous component that projects light or magnetic fields onto the photoconductive or IFE layer 2302. This projection is guided by the instructions from the CPU 2312, which uses the real-time chip feedback 2308 to dynamically adjust and optimize the circuit's configuration, ensuring that it meets the required operational parameters. The feedback loop established between the camera 2304, the chip, and the CPU 2312 allows for continuous real-time monitoring and adjustment, making the system highly adaptable and efficient. The CPU's AI-driven light masking capability ensures that the circuit paths can be reconfigured on-the-fly based on the specific demands of the task or input it receives, which is particularly advantageous in applications such as neuromorphic computing, photonic processing, and other advanced electronic systems that require rapid and dynamic circuit reconfiguration. The system's ability to employ either a photoconductive gel layer or an IFE photo magnetic nanoparticle layer makes it versatile, offering multiple approaches to achieving reconfigurable and responsive circuitry.

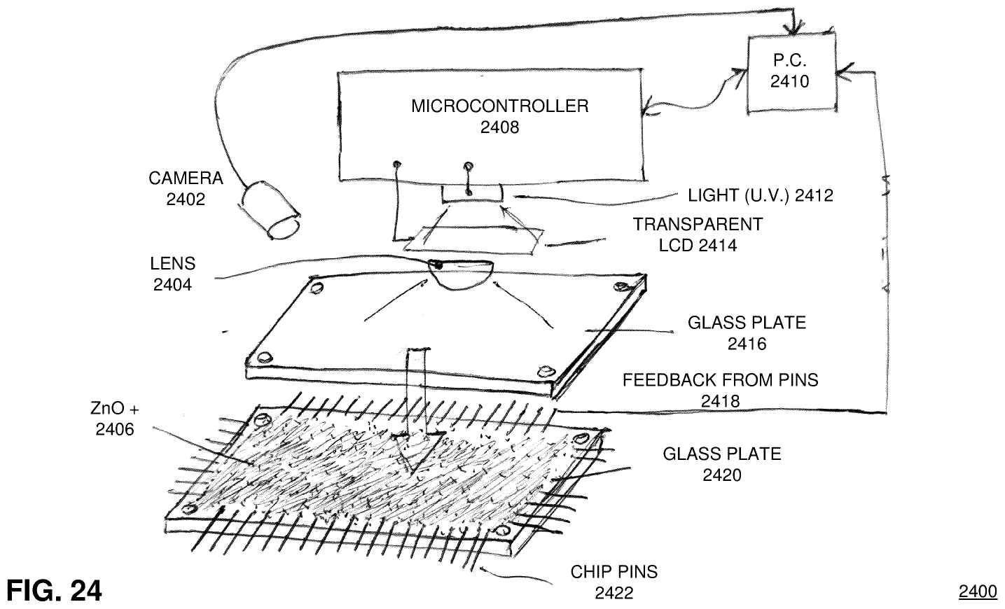

FIG. 24 is an illustrative setup showcasing a sophisticated photonic circuit system designed for dynamic reconfiguration and real-time monitoring through advanced optical and electronic integration. In FIG. 24, the system 2400 incorporates multiple interconnected components that work in harmony to achieve precise control over circuit formation and behavior on a photoconductive substrate. The camera 2402, strategically positioned above the lens 2404, is configured to capture high-resolution images and video of the entire circuit formation process. This camera provides advantageous feedback to the system, enabling real-time monitoring and adjustment of the circuit pathways as they form on the photoconductive ZnO+layer 2406. The camera's feedback is advantageous for ensuring that the light patterns generated by the system produce the desired circuit configurations. The lens 2404 is advantageous aligned to focus ultraviolet (UV) light 2412 (see, e.g., Wang et al., “Photonic-circuit-integrated titanium: sapphire laser,” Nat. Photon. 17, 338-345, 26 Jan. 2023, incorporated by reference herein) onto the photoconductive layer 2406. This lens is engineered to maintain the integrity of the light's wavelength and intensity, ensuring that the UV light is precisely directed onto the target areas of the ZnO+layer. The photoconductive ZnO+layer 2406, composed of Zinc Oxide mixed with other materials (e.g., potentially including stabilizing agents or other additives to enhance its photoconductive properties), plays an advantageous role in the system. This layer exhibits variable conductivity in response to the UV light, allowing it to create or modify circuit paths dynamically as light interacts with its surface. The microcontroller 2408 is a central control unit that orchestrates the operation of the UV light source 2412 and the transparent LCD 2414. It receives commands from the PC 2410, which acts as the brain of the system, processing data and executing software algorithms designed to manage the entire photonic circuit configuration process. The PC 2410 is equipped with specialized software capable of generating precise light masks or patterns, which are then displayed on the transparent LCD 2414. The transparent LCD 2414 is a high-resolution display that serves as the interface between the UV light source and the photoconductive layer. It displays intricate circuit patterns or light masks, which the UV light passes through, selectively activating regions of the ZnO+layer 2406 beneath. The ability to control the display on the LCD allows for an immense degree of flexibility and precision in circuit design, as different patterns can be quickly generated and projected onto the layer without physical alterations to the setup. The UV light source 2412 is configured to emit light within the 365-370 nm wavelength range, with an intensity of 4500-5000 mW and a forward current (I.F.) of 1050 mA. This specific configuration is chosen to match the photoconductive properties of the ZnO+layer, ensuring optimal activation of the material's conductivity in the desired areas. The system is constructed with two glass plates 2416 and 2420, which encase the ZnO+layer. The first glass plate 2416 allows the UV light to pass through while providing a stable platform for the layer. The second glass plate 2420, positioned below the ZnO+layer, serves as a structural component that supports the overall setup and maintains the alignment of the layers. The transparent nature of these plates ensures that the UV light can reach the photoconductive layer without obstruction, while also protecting the delicate materials from external contaminants or mechanical stress. Feedback from pins 2418 is collected from the activated circuits on the ZnO+layer. This feedback is advantageous for the system to assess the current state of the circuits and to make any advantageous adjustments to the light patterns or system parameters. The data from these pins is sent back to the microcontroller 2408 and PC 2410, where it is analyzed to determine the effectiveness of the current light configuration and to make real-time corrections if needed. The chip pins 2422 provide an advantageous interface between the newly formed circuits on the ZnO+layer and any external systems or circuits. These pins facilitate the transfer of electrical signals, allowing the reconfigured circuits to be integrated into broader electronic systems, thereby extending the functionality of the photonic circuit setup into practical applications. Overall, FIG. 24 demonstrates a highly advanced photonic system capable of dynamically creating and reconfiguring circuits through precise control of light and material properties, with extensive real-time feedback mechanisms that ensure accuracy and adaptability in circuit design.

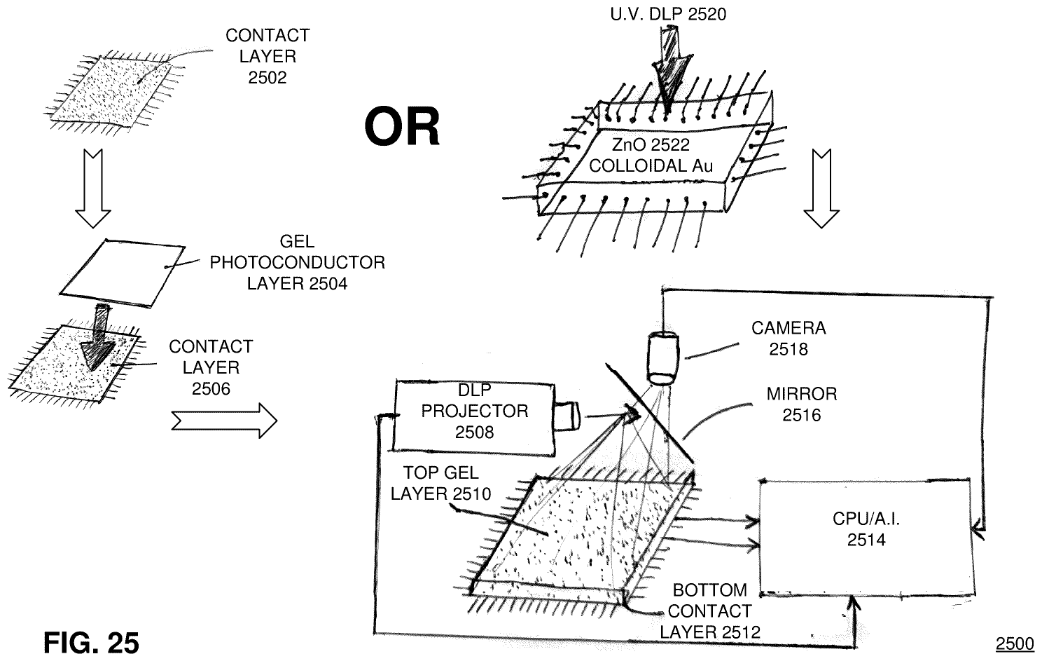

FIG. 25 is an illustrative setup that demonstrates a complex and adaptable photonic circuit system designed to leverage advanced materials and dynamic optical control for the reconfiguration of electronic circuits in real-time. In FIG. 25, the system 2500 incorporates various layers and components that interact to achieve precise and adaptable circuit formation on a photoconductive substrate. The contact layers 2502, 2506, and 2512 are advantageous, providing a conductive interface that allows electrical signals to interact with the photoconductive or ZnO-based layers. These contact layers are advantageously placed above and below the photoconductive materials to facilitate dynamic reconfiguration of circuits as light is projected onto them. The gel photoconductor layers 2504 and 2510 are advantageous to the system's operation, including materials that exhibit variable conductivity in response to light, allowing for the formation or alteration of circuit paths in real time. An advantageous feature of the system is the ZnO+colloidal Au layer 2522, which is designed to enhance the photoconductive properties of the ZnO, advantageously increasing its responsiveness and sensitivity to the UV light emitted by the DLP projector or laser 2508, 2520 (see, e.g., Wang et al., “Photonic-circuit-integrated titanium: sapphire laser,” Nat. Photon. 17, 338-345, 26 Jan. 2023, incorporated by reference herein). The DLP projector is configured to emit precise light patterns onto the photoconductive layers, which in turn modify the electrical pathways within the contact layers. The light emitted by the DLP projector is advantageously directed by the mirror 2516, ensuring that it reaches the target areas on the photoconductive or ZnO layers with optimal accuracy. The system also incorporates a camera 2518, which is positioned above the setup to capture real-time images or video of the circuit formation process. This camera provides continuous feedback to the CPU/A.I. system 2514, which processes the visual data and adjusts the light patterns emitted by the DLP projector as necessary to ensure that the circuits are forming as intended. The CPU/A.I. system 2514 is the brain of the operation, processing input from the camera and controlling the DLP projector to create the desired circuit configurations. This setup also includes top and bottom gel layers 2510 and 2512, which interact with the light patterns to enhance the formation of circuit paths or provide structural support to the overall assembly. The dynamic interplay between the light, photoconductive materials, and conductive layers allows the system to create and modify circuits on-the-fly, offering a highly flexible platform for developing advanced electronic devices. The integration of real-time monitoring and feedback mechanisms ensures that the system can adapt to changes and maintain precise control over the circuit formation process. Overall, FIG. 25 showcases an advantageous photonic circuit system capable of dynamic reconfiguration through the precise control of light and material properties, making it an advantageous tool for prototyping and developing next-generation electronic systems.

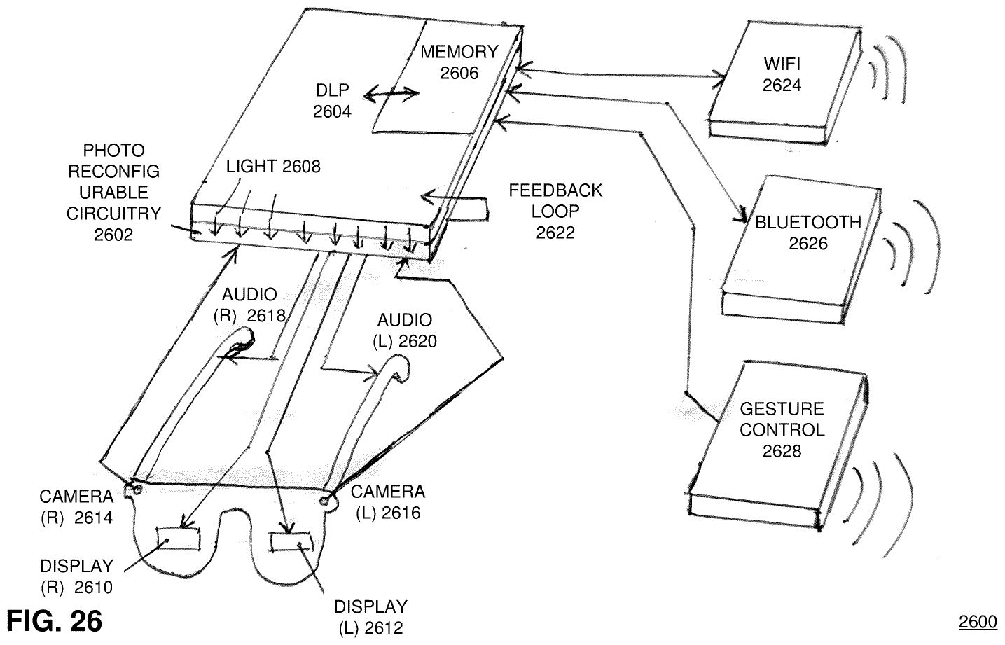

FIG. 26 is an illustrative setup showcasing an advanced photonic and electronic system designed for dynamic reconfiguration of circuitry using light-based inputs, real-time feedback mechanisms, and integrated wireless communication technologies. In FIG. 26, the system 2600 is particularly well-suited for applications such as augmented reality (AR) and virtual reality (VR) systems, where adaptable and responsive circuitry is essential for processing, display, and user interaction functions. Photo Reconfigurable Circuitry 2602 forms the core of the system, enabling flexible modification of circuits in response to predetermined light patterns. This reconfigurable circuitry supports ZnO or Inverse Faraday Effect (IFE) architectures with a contact point array, allowing for dynamic adjustments in circuit configuration. The system's adaptability makes it ideal for use in AR/VR systems that require real-time responsiveness. A DLP (Digital Light Processing) module or laser 2604 (see, e.g., Wang et al., “Photonic-circuit-integrated titanium: sapphire laser,” Nat. Photon. 17, 338-345, 26 Jan. 2023, incorporated by reference herein) is employed to project these patterns with precision. The DLP utilizes stored data from memory 2606, which holds configuration data, instructions, and previous circuit states, making the system highly adaptable to the changing demands of AR/VR environments. The light 2608 generated by the DLP interacts directly with the reconfigurable circuitry, where its wavelength, intensity, and pattern are precisely controlled to modify the circuitry's configuration in real-time. The system is equipped with left and right displays 2610, 2612 that provide real-time visual feedback, displaying statuses, configurations, and other advantageous information. This feature is advantageous in AR/VR systems, where real-time display accuracy is advantageous for maintaining an immersive experience. Cameras 2614 (R) and 2616 (L) are advantageously positioned to capture high-resolution images of the ongoing reconfiguration process. This visual data is fed into a feedback loop 2622, an advantageous element for ensuring the system remains accurate and responsive to environmental changes or user interactions. The cameras also support real-time video processing, contributing to the overall system's responsiveness and precision. Audio components 2618 (R) and 2620 (L) provide auditory feedback, enhancing the user interface with sound cues that correspond to system changes or user interactions. This feature is particularly useful in AR/VR applications, where audio feedback can significantly enhance user experience. Wireless communication is enabled through integrated Wi-Fi 2624 and Bluetooth 2626 modules, allowing the system to connect to networks and devices for remote control, data transmission, and updates. The Wi-Fi chip also facilitates AirPlay 2 and internet connectivity, essential for streaming and other network-dependent functions in AR/VR environments. A gesture control chip 2628 adds an intuitive layer of interaction, enabling users to manage the system through physical gestures, which is particularly advantageous in AR/VR environments where traditional input methods may be impractical. This gesture control capability can be integrated with Meta's Neural Interface wristbands, allowing these wristbands to be used as a virtual keyboard, with the input displayed directly in XREAL PRO 2 AR glasses. The interconnected nature of these components—from the memory to the DLP, feedback loop, wireless modules, and off-the-shelf devices like XREAL glasses—enables the system to operate seamlessly, with each part playing an advantageous role in achieving precise and adaptable circuit reconfiguration. The integration with XREAL glasses allows for immersive AR video display, and the system can be tailored to interact seamlessly with external hardware through Bluetooth and Wi-Fi connections. This setup is designed to meet the rigorous demands of AR/VR and other advanced applications, where dynamic and responsive circuitry is advantageous. The system's ability to support real-time camera video processing, feedback from reconfigurable circuitry to the DLP, and integration with widely available consumer electronics like XREAL glasses and Meta's Neural Interface Wristbands makes it a cutting-edge platform capable of delivering flexible, real-time control and interaction for the next generation of electronic systems.

Advantageously, the photonic chips and reconfigurable circuitry of FIGS. 14-26 can leverage the IFE to induce magnetic fields optically (see, e.g., Cheng et al., “Light-induced magnetism in plasmonic gold nanoparticles,” Nat. Photon. 14, 365, 16 Mar. 2020, incorporated by reference herein), allowing for dynamic control of circuit paths without physical alterations. This is particularly useful where photoconductive or magnetically responsive materials are used in conjunction with light to configure or reconfigure circuits on-the-fly. The Zinc Oxide (ZnO) photoconductors plasmonic effects in nanoparticles can complement the use of ZnO in creating optoelectronic components. By combining ZnO layers with plasmonic nanoparticles, sensitivity and control of light-induced circuit paths can be enhanced. This approach can be applied in the UV-activated circuit designs and A.I. Defined Photonic Chips to improve the precision and response time of optoelectronic switching. The Magnetic Field Effect Transistor (MFET) can employ magnetic control using IFE to induce magnetism in specific regions of a circuit adapted to the Bipolar Magnetic Field Effect Transistor (MFET) designs. Instead of relying solely on permanent magnets or external magnetic fields, the IFE allows for optical control of the magnetic fields, making the transistor operation faster and more efficient, and potentially allowing for finer control over the magnetic properties. The neuromorphic processing can employ dynamic reconfiguration with the ability to use light to dynamically reconfigure magnetic fields at a nanoscale to create adaptive and reconfigurable processors. The subpicosecond response times observed in the IFE can contribute to the development of processors capable of real-time adaptation and learning, by modifying the connections within the chip based on optical inputs. The quantum dots and nanoparticles employed in the photonic chips include the use of quantum dots or nanoscale metal contacts (e.g., as mentioned in the photonic processor) can employ the IFE techniques by utilizing the plasmonic effects to enhance the interaction between light and the quantum dots. This can lead to more efficient and powerful photonic chips with applications in quantum computing and advanced optoelectronics. All-optical processing with elimination of external magnetic fields can be used to create all-optical circuits without the need for external magnetic fields, for developing environmentally friendly, efficient processors. Implementing these techniques simplifies the design and reduces the power requirements of the circuits, making them more suitable for large-scale integration.

As previously described, the lasers employed in any of FIGS. 14-26, for example, chip-sized titanium-doped sapphire laser (see, e.g., Wang et al., “Photonic-circuit-integrated titanium: sapphire laser,” Nat. Photon. 17, 338-345, 26 Jan. 2023, incorporated by reference herein) can serve as a light source for circuits involving UV light and photonic circuits. The laser is chip-sized, making it highly compatible with integrated circuit designs and useful for embedding within the photonic or neuromorphic processors. The wavelength flexibility of the titanium-doped sapphire lasers, which are tunable across a broad range of wavelengths, typically spanning from the near-infrared to visible light, can be optimized to emit UV light, which is advantageous for the applications involving ZnO thin films or UV-induced photonic circuits. High intensity and precision of these lasers can be used precise control, making them ideal for tasks that employ focused energy delivery, such as activating specific areas of a photonic chip or triggering the Inverse Faraday Effect in magnetic nanoparticles. The photonic neuromorphic processors can employ such lasers to control the photonic circuits within the A.I. defined photonic neuromorphic processor. By tuning the laser to the appropriate UV wavelength, it could interact with ZnO or other photoconductive materials to dynamically reconfigure the chip. Optoelectronic switching due to the high intensity and tunability of the laser make it suitable for optoelectronic switches in the circuits, where precise control over light-induced magnetism or conductivity is employed. Dynamic circuit reconfiguration can employ the laser to write, erase, or modify circuit paths on the photonic chips by precisely targeting areas of the ZnO thin film or other responsive materials, thereby changing their conductive states. Quantum computing employing quantum dots or other nanoscale components, can employ the laser's precision to enable fine-tuned manipulation of quantum states, essential for quantum computing applications. The UV photonic systems can employ the tunability to UV wavelengths of the laser to replace or complement the UV DLP systems, offering a more integrated and more powerful light source.

The ZnO films employed in any of FIGS. 14-26 exhibit photoconductive properties, meaning their electrical conductivity increases when exposed to light, particularly UV light. This characteristic is advantageous, where light is used to dynamically control circuit paths. The transparency of the ZnO films to visible light, make them suitable for applications where light needs to pass through multiple layers or where visibility of underlying components is advantageous. This transparency is advantageous for photonic circuits where precise control of light pathways is employed. Flexible application of ZnO films allows them to be deposited on flexible substrates, allowing for the creation of flexible circuits or wearable electronics. This aligns with the present concepts that involve flexible photonic chips and reconfigurable circuitry. Synthesis and deposition techniques like sol-gel processing, sputtering, and ultrasonic-assisted deposition can be employed to create these ZnO films. These methods allow for fine control over film thickness and properties, which is advantageous for tailoring the film to specific applications. The A.I. Defined Photonic Neuromorphic Processor can employ the photoconductive ZnO film, where it serves as the medium through which light from a UV source (like the titanium-doped sapphire laser) induces conductivity. The transparency allows for stacking or layering different functional materials without obstructing the light. The dynamic circuit reconfiguration via the ZnO films can be used in reconfigurable circuits where light exposure alters the circuit's state. For example, specific regions of the film can be activated to connect or disconnect circuit pathways dynamically. The Magnetic Field Effect Transistor (MFET), involving magnetic field effects, can employ the ZnO's response to light and be combined with magnetic fields to create transistors that switch states based on both optical and magnetic inputs. The quantum dots and optoelectronic devices can employ a combination of ZnO films with quantum dots or nanodots to create advanced optoelectronic devices, where the photoconductivity of the ZnO enhances the performance of quantum-based components. The ZnO transparent photoconductive films provide a flexible, responsive material that can be precisely controlled using light. This enhances the reconfigurability and functionality of the photonic and neuromorphic devices.

The above-described devices and subsystems of the illustrative embodiments can include, for example, any suitable servers, workstations, PCs, laptop computers, PDAs, Internet appliances, handheld devices, cellular telephones, wireless devices, other devices, and the like, capable of performing the processes of the illustrative embodiments. The devices and subsystems of the illustrative embodiments can communicate with each other using any suitable protocol and can be implemented using one or more programmed computer systems or devices.

One or more interface mechanisms can be used with the illustrative embodiments, including, for example, Internet access, telecommunications in any suitable form (e.g., voice, modem, and the like), wireless communications media, and the like. For example, employed communications networks or links can include one or more wireless communications networks, cellular communications networks, G3 communications networks, Public Switched Telephone Network (PSTNs), Packet Data Networks (PDNs), the Internet, intranets, a combination thereof, and the like.

It is to be understood that the devices and subsystems of the illustrative embodiments are for illustrative purposes, as many variations of the specific hardware used to implement the illustrative embodiments are possible, as will be appreciated by those skilled in the relevant art(s). For example, the functionality of one or more of the devices and subsystems of the illustrative embodiments can be implemented via one or more programmed computer systems or devices.

To implement such variations as well as other variations, a single computer system can be programmed to perform the special purpose functions of one or more of the devices and subsystems of the illustrative embodiments. On the other hand, two or more programmed computer systems or devices can be substituted for any one of the devices and subsystems of the illustrative embodiments. Accordingly, principles and advantages of distributed processing, such as redundancy, replication, and the like, also can be implemented, as desired, to increase the robustness and performance of the devices and subsystems of the illustrative embodiments.

The devices and subsystems of the illustrative embodiments can store information relating to various processes described herein. This information can be stored in one or more memories, such as a hard disk, optical disk, magneto-optical disk, RAM, and the like, of the devices and subsystems of the illustrative embodiments. One or more databases of the devices and subsystems of the illustrative embodiments can store the information used to implement the illustrative embodiments of the present disclosures. The databases can be organized using data structures (e.g., records, tables, arrays, fields, graphs, trees, lists, and the like) included in one or more memories or storage devices listed herein. The processes described with respect to the illustrative embodiments can include appropriate data structures for storing data collected and/or generated by the processes of the devices and subsystems of the illustrative embodiments in one or more databases thereof.

All or a portion of the devices and subsystems of the illustrative embodiments can be conveniently implemented using one or more general purpose computer systems, microprocessors, digital signal processors, micro-controllers, and the like, programmed according to the teachings of the illustrative embodiments of the present disclosures, as will be appreciated by those skilled in the computer and software arts. Appropriate software can be readily prepared by programmers of ordinary skill based on the teachings of the illustrative embodiments, as will be appreciated by those skilled in the software art. Further, the devices and subsystems of the illustrative embodiments can be implemented on the World Wide Web. In addition, the devices and subsystems of the illustrative embodiments can be implemented by the preparation of application-specific integrated circuits or by interconnecting an appropriate network of conventional component circuits, as will be appreciated by those skilled in the electrical art(s). Thus, the illustrative embodiments are not limited to any specific combination of hardware circuitry and/or software.

Stored on any one or on a combination of computer readable media, the illustrative embodiments of the present disclosures can include software for controlling the devices and subsystems of the illustrative embodiments, for driving the devices and subsystems of the illustrative embodiments, for enabling the devices and subsystems of the illustrative embodiments to interact with a human user, and the like. Such software can include, but is not limited to, device drivers, firmware, operating systems, development tools, applications software, and the like. Such computer readable media further can include the computer program product of an embodiment of the present disclosures for performing all or a portion (if processing is distributed) of the processing performed in implementing the disclosures. Computer code devices of the illustrative embodiments of the present disclosures can include any suitable interpretable or executable code mechanism, including but not limited to scripts, interpretable programs, dynamic link libraries (DLLs), Java classes and applets, complete executable programs, Common Object Request Broker Architecture (CORBA) objects, and the like. Moreover, parts of the processing of the illustrative embodiments of the present disclosures can be distributed for better performance, reliability, cost, and the like.

As stated above, the devices and subsystems of the illustrative embodiments can include computer readable medium or memories for holding instructions programmed according to the teachings of the present disclosures and for holding data structures, tables, records, and/or other data described herein. Computer readable medium can include any suitable medium that participates in providing instructions to a processor for execution. Such a medium can take many forms, including but not limited to, non-volatile media, volatile media, transmission media, and the like. Non-volatile media can include, for example, optical or magnetic disks, magneto-optical disks, and the like. Volatile media can include dynamic memories, and the like. Transmission media can include coaxial cables, copper wire, fiber optics, and the like. Transmission media also can take the form of acoustic, optical, electromagnetic waves, and the like, such as those generated during radio frequency (RF) communications, infrared (IR) data communications, and the like. Common forms of computer-readable media can include, for example, a floppy disk, a flexible disk, hard disk, magnetic tape, any other suitable magnetic medium, a CD-ROM, CDRW, DVD, any other suitable optical medium, punch cards, paper tape, optical mark sheets, any other suitable physical medium with patterns of holes or other optically recognizable indicia, a RAM, a PROM, an EPROM, a FLASH-EPROM, any other suitable memory chip or cartridge, a carrier wave or any other suitable medium from which a computer can read.

While the present disclosures have been described in connection with a number of illustrative embodiments, and implementations, the present disclosures are not so limited, but rather cover various modifications, and equivalent arrangements, which fall within the purview of pending claims.

What is claimed is:

1. A dynamically reconfigurable circuit, the circuit comprising:
a photoconductive layer responsive to light, wherein the photoconductive layer modifies an electrical conductivity thereof in accordance with a pattern of light projected onto the photoconductive layer;
a digital light processing (DLP) module configured to project the pattern of light onto the photoconductive layer, wherein the light is selectively patterned to reconfigure circuit pathways within the photoconductive layer; and
a memory coupled to the DLP module, the memory configured to store configuration data and instructions for controlling the light patterns projected by the DLP module.

2. The circuit of claim 1, further comprising:
a feedback loop operatively connected to the DLP module and configured to generate real-time data from the photoconductive layer, wherein the DLP module is configured to adjust the light patterns in response to the real-time data.

3. The circuit of claim 1, further comprising:
a processor in communication with the DLP module and the feedback loop and configured to execute instructions stored in the memory to manage dynamic reconfiguration of the photoconductive layer.

4. The circuit of claim 1, wherein the digital light processing (DLP) module comprises an on-chip sapphire laser configured to project the light patterns onto the photoconductive layer.

5. The circuit of claim 1, wherein the photoconductive layer comprises an Inverse Faraday Effect (IFE) photo-magnetic nanoparticle layer, configured to alter magnetic and electrical properties thereof in response to light and magnetic fields.

6. The circuit of claim 1, wherein the circuit is implemented as an Application-Specific Integrated Circuit (ASIC).

7. A method for dynamically reconfiguring circuits, the method comprising:
modifying an electrical conductivity of a photoconductive layer responsive to light in accordance with a pattern of light projected onto the photoconductive layer;
projecting with a digital light processing (DLP) module the pattern of light onto the photoconductive layer, and selectively patterning the light to reconfigure circuit pathways within the photoconductive layer; and
storing on a memory coupled to the DLP module configuration data and instructions, and controlling the light patterns projected by the DLP module.

8. The method of claim 7, further comprising:
generating real-time data from the photoconductive layer with a feedback loop operatively connected to the DLP module; and
adjusting with the DLP module the light patterns in response to the real-time data.

9. The method of claim 7, further comprising:
executing instructions stored in the memory with the processor in communication with the DLP module; and
managing with the processor dynamic reconfiguration of the photoconductive layer.

10. The method of claim 7, further comprising:
projecting the light patterns onto the photoconductive layer with an on-chip sapphire laser in the digital light processing (DLP) module.

11. The method of claim 7, further comprising:
altering magnetic and electrical properties in the photoconductive layer in response to light and magnetic fields with an Inverse Faraday Effect (IFE) photo-magnetic nanoparticle layer in the photoconductive layer.

12. The method of claim 7, further comprising:
implementing the circuit as an Application-Specific Integrated Circuit (ASIC).

13. A computer program product for dynamically reconfiguring circuits, the computer program product comprising a non-transitory computer-readable medium having program instructions stored thereon, the program instructions, when executed by a processor, cause the processor to perform the steps of:
modifying an electrical conductivity of a photoconductive layer responsive to light in accordance with a pattern of light projected onto the photoconductive layer;
projecting with a digital light processing (DLP) module the pattern of light onto the photoconductive layer, and selectively patterning the light to reconfigure circuit pathways within the photoconductive layer; and
storing on a memory coupled to the DLP module configuration data and instructions, and controlling the light patterns projected by the DLP module.

14. The computer program product of claim 13, further comprising:
generating real-time data from the photoconductive layer with a feedback loop operatively connected to the DLP module; and
adjusting with the DLP module the light patterns in response to the real-time data.

15. The computer program product of claim 13, further comprising:
executing instructions stored in the memory with the processor in communication with the DLP module; and
managing with the processor dynamic reconfiguration of the photoconductive layer.

16. The computer program product of claim 13, further comprising:
projecting the light patterns onto the photoconductive layer with an on-chip sapphire laser in the digital light processing (DLP) module.

17. The computer program product of claim 13, further comprising:
altering magnetic and electrical properties in the photoconductive layer in response to light and magnetic fields with an Inverse Faraday Effect (IFE) photo-magnetic nanoparticle layer in the photoconductive layer.

18. The computer program product of claim 13, further comprising:
implementing the circuit as an Application-Specific Integrated Circuit (ASIC).
